(19) United States
(12) Patent Application Publication
(10) Pub. No.: US 2024/0321723 A1
(43) Pub. Date: Sep. 26, 2024

(54) STRUCTURE TO MITIGATE VERTICAL INTERCONNECT ACCESS INDUCED METAL CORROSION

(71) Applicant: Taiwan Semiconductor Manufacturing Company, Ltd., Hsinchu (TW)

(72) Inventors: Shu-Hui SU, Tucheng City (TW); Hsin-Li CHENG, Hsinchu (TW); YingKit Felix TSUI, Cupertino, CA (US)

(21) Appl. No.: 18/186,545

(22) Filed: Mar. 20, 2023

(51) Int. Cl. H01L 23/522; H01L 23/58

(52) U.S. Cl. CPC H01L 23/5223; H01L 23/585; H01L 28/87; H01L 28/91

(57) ABSTRACT

Some implementations described herein provide techniques and apparatuses for forming a semiconductor die including a discharge management structure. The discharge management structure may include contact structures (e.g., vertical interconnect access structures, or “vias”) connecting a metal layer to electrode layers of a capacitor structure and to a substrate below the capacitor structure. The contact structures have different cross-sectional areas that, based on Kirchhoff's law, increase a voltage drop between the capacitor structure and the silicon substrate. The voltage drop may reduce a likelihood of an electrical discharge by the capacitor structure that causes damage to the metal layer. By reducing the likelihood of damage to the metal layer, defects that may be associated with vertical interconnect access induced metal island corrosion may be reduced.

### BACKGROUND

Various semiconductor die packing techniques may be used to incorporate one or more semiconductor dies into a semiconductor die package. In some cases, semiconductor dies may be stacked in a semiconductor die package to achieve a smaller horizontal or lateral footprint of the semiconductor die package and/or to increase the density of the semiconductor die package. Semiconductor die packing techniques that may be performed to integrate a plurality of semiconductor dies in a semiconductor die package may include integrated fanout (InFO), package on package (POP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor die package described herein.

FIGS. 3A and 3B are diagrams of an example implementation of contact structures described herein.

FIGS. 4A-4C are diagrams of an example implementation of a trench capacitor structure described herein.

FIGS. 5A-5C are diagrams of an example implementation of wafer-based substrate including a structure described herein.

FIGS. 6A-6E are diagrams of an example implementation of forming a semiconductor die described herein.

FIGS. 7A-7D are diagrams of an example implementation of forming a semiconductor die described herein.

FIGS. 8A-8E are diagrams of an example implementation of forming a portion of a semiconductor die package described herein.

FIG. 9 is a diagram of example components of a device described herein.

FIG. 10 is a flowchart of an example process associated with forming a structure to mitigate vertical interconnect access induced metal corrosion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die includes a capacitor structure (e.g., deep trench capacitor structure) that connects to contact structures (e.g., vias) through a metal layer. Formation of the contact structures may include an etching operation that, while forming cavities for the contact structures, forms thinned portions within the metal layer. Further, formation of the contact structures may include a wet cleaning operation that cleans the cavities. During the wet cleaning operation, the capacitor structure may discharge an accumulated electrical charge and damage the thinned portions. Such damage may cause vertical interconnect access induced metal island corrosion defects in the semiconductor die.

Some implementations described herein provide techniques and apparatuses for forming a semiconductor die including a discharge management structure. The discharge management structure may include contact structures (e.g., vertical interconnect access structures, or “vias”) connecting a metal layer to electrode layers of a capacitor structure and to a substrate below the capacitor structure. The contact structures have different cross-sectional areas that, based on Kirchhoff's law, increase a voltage drop between a capacitor structure and the silicon substrate. The voltage drop may reduce a likelihood of an electrical discharge by the capacitor structure that causes damage to the metal layer. By reducing the likelihood of damage to the metal layer, defects that may be associated with vertical interconnect access induced metal island corrosion (VIMIC) may be reduced.

In this way, a likelihood of defects attributable to VIMIC within the semiconductor dic may decrease relative to another semiconductor die not including the discharge management structure. By decreasing the likelihood of such defects, a yield of the semiconductor die may increase to reduce an amount of resources needed to fabricate a volume of the semiconductor die (e.g., semiconductor manufacturing tools, raw materials, manpower, and/or computing resources).

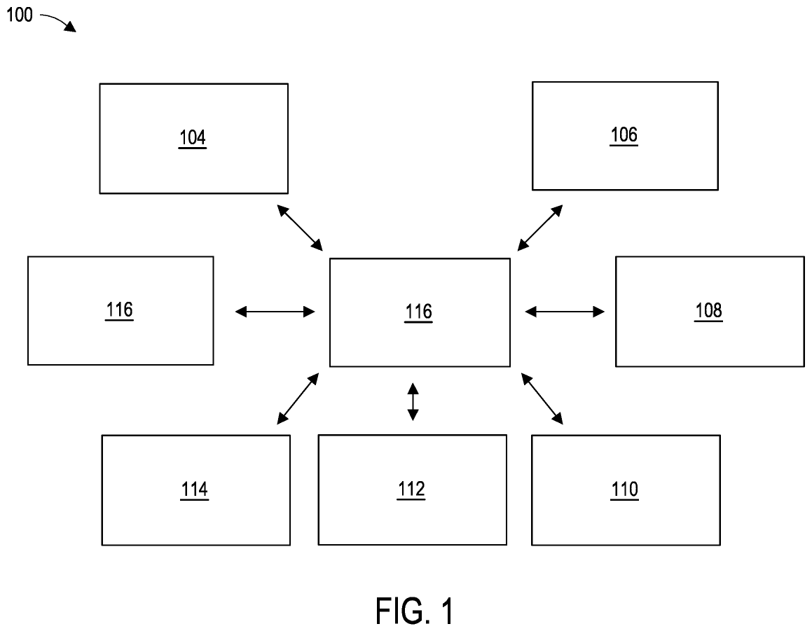

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor die layer patterns for forming one or more semiconductor dies, may include a pattern for forming one or more structures of a semiconductor die, may include a pattern for etching various portions of a semiconductor die, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor die. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor die. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor die with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor die). The polishing pad and the semiconductor die may be pressed together by a dynamic polishing head and held in place by the retaining ring. The dynamic polishing head may rotate with different axes of rotation to remove material and even out any irregular topography of the semiconductor die, making the semiconductor die flat or planar.

The plating tool 112 is a semiconductor processing tool that is capable of plating a substrate (e.g., a wafer, a semiconductor die, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor dies, two or more semiconductor dies) together. For example, the bonding tool 114 may include a direct bonding tool. A direct bonding tool is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor dies between semiconductor processing tools 102-114, that is configured to transport substrates and/or semiconductor dies between processing chambers of the same semiconductor processing tool, and/or that is configured to transport substrates and/or semiconductor dies to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor dies between the plurality of processing chambers, to transport substrates and/or semiconductor dies between a processing chamber and a buffer area, to transport substrates and/or semiconductor dies between a processing chamber and an interface tool such as an equipment front end module (EFEM), and/or to transport substrates and/or semiconductor dies between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor die) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor dies between the processing chambers of the deposition tool 102 without breaking or removing a vacuum (or an at least partial vacuum) between the processing chambers and/or between processing operations in the deposition tool 102.

In some implementations, one or more of the semiconductor processing tools 102-114 and/or the wafer/die transport tool 116 may perform a series of semiconductor processing operations described herein. As an example, the series of semiconductor operations includes forming, on or within a substrate, a trench capacitor structure including a first electrode layer and a second electrode layer. The series of semiconductor processing operations includes forming a dielectric layer over the trench capacitor structure and forming a first electrode contact structure that has a first cross-sectional area and that penetrates through the dielectric layer to the first electrode layer. The series of semiconductor processing operations further includes forming a second electrode contact structure that has a second cross-sectional area and that penetrates through the dielectric layer to the second electrode layer and forming a substrate contact structure that has a third cross-sectional area and that penetrates through the dielectric layer to the substrate.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

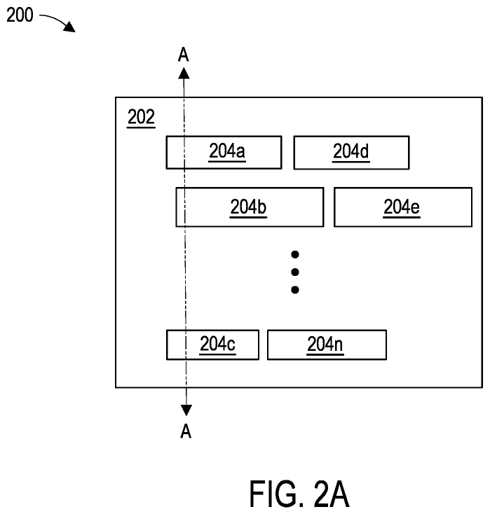

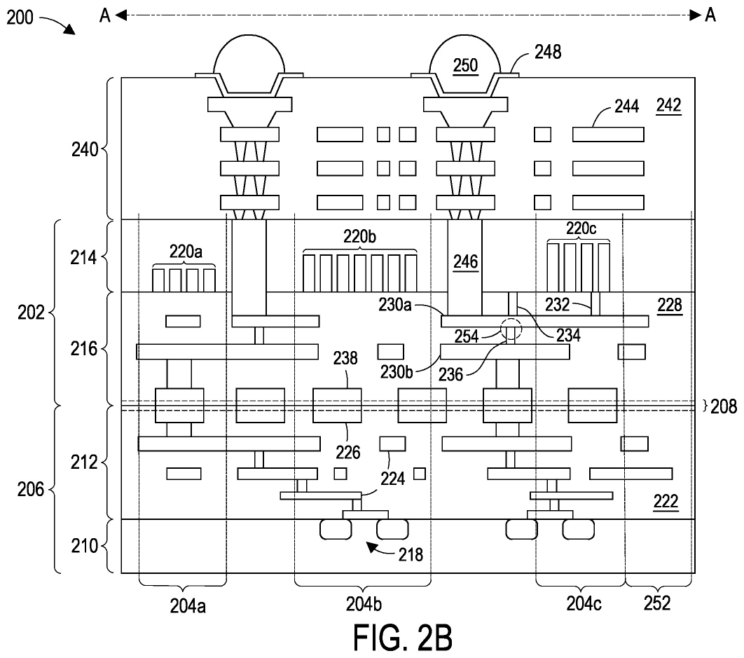

FIGS. 2A and 2B are diagrams of an example semiconductor die package 200 described herein. The semiconductor die package 200 includes an example of a wafer on wafer (WoW) semiconductor die package, a die on wafer semiconductor die package, a die on die semiconductor die package, or another type of semiconductor die package in which semiconductor dies are directly bonded and vertically arranged or stacked. FIG. 2A illustrates a top-down view of a portion of the semiconductor die package 200. FIG. 2B illustrates a cross-section view of a portion of the semiconductor die package 200 along line A-A in FIG. 2A.

As shown in FIG. 2A, the semiconductor die package 200 may include a first semiconductor die 202 and a plurality of trench capacitor regions 204a-204n in the first semiconductor die 202. The trench capacitor regions 204a-204n may be horizontally arranged in the first semiconductor die 202. The trench capacitor regions 204a-204n may include various sizes and/or shapes to provide a sufficient amount of decoupling capacitance across the semiconductor die package 200 for the circuits and semiconductor dies of the semiconductor die package 200.

As shown in FIG. 2B, the semiconductor die package 200 includes the first semiconductor die 202 and a second semiconductor die 206. In some implementations, the semiconductor die package 200 includes additional semiconductor dies. The first semiconductor die 202 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally, and/or alternatively, the first semiconductor die 202 may include a memory die, an input/output (I/O) die, a pixel sensor die, and/or another type of semiconductor die. A memory die may include a static random access memory (SRAM) die, a dynamic random access memory (DRAM) die, a NAND dic, a high bandwidth memory (HBM) die, and/or another type of memory die. In some implementations, the second semiconductor die 206 includes the same type of semiconductor die as the first semiconductor dic 202. In some implementations, the second semiconductor die 206 includes a different type of semiconductor die than the first semiconductor die 202.

The first semiconductor die 202 and the second semiconductor die 206 may be bonded together (e.g., directly bonded) at a bonding interface 208. In some implementations, one or more layers may be included between the first semiconductor die 202 and the second semiconductor die 206 at the bonding interface 208, such as one or more passivation layers, one or more bonding films, and/or one or more layers of another type.

The second semiconductor die 206 may include a device region 210 and an interconnect region 212 adjacent to and/or above the device region 210. In some implementations, the second semiconductor die 206 may include additional regions. Similarly, the first semiconductor die 202 may include a device region 214 and an interconnect region 216 adjacent to and/or below the device region 214. In some implementations, the first semiconductor die 202 may include additional regions. The first semiconductor die 202 and the second semiconductor die 206 may be bonded at the interconnect region 212 and the interconnect region 216. The bonding interface 208 may be located at a first side of the interconnect region 216 facing the interconnect region 212 and corresponding to a first side of the second semiconductor die 206.

The device regions 210 and 214 may each include a semiconductor substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The device region 210 of the second semiconductor die 206 may include one or more semiconductor devices 218 included in the semiconductor substrate of the device region 210. The semiconductor devices 218 may include one or more transistors (e.g., planar transistors, fin field effect transistors (FinFETs), nanosheet transistors (e.g., gate all around (GAA) transistors), memory cells, capacitors, inductors, resistors, pixel sensors, circuits (e.g., integrated circuits (ICs)), and/or another type of semiconductor dies. In some implementations, the device region 210 includes logic circuitry.

As further shown in FIG. 2B, the device region 214 of the first semiconductor die 202 may include a plurality of trench capacitor structures 220a-220c in the semiconductor substrate of the device region 214. Respective pluralities of the trench capacitor structures 220a-220c may be included in different trench capacitor regions in the device region 214. For example, the trench capacitor structure 220a may be included in the trench capacitor region 204a, the trench capacitor structure 220b may be included in the trench capacitor region 204b, the trench capacitor structure 220c may be included in the trench capacitor region 204c, and so on. The trench capacitor structures 220a-220c may be configured to provide a decoupling capacitance for the one or more semiconductor devices 218 of the second semiconductor die 206.

At least two or more of the respective pluralities of trench capacitor structures 220a-220c may be formed to different depths (or heights) in the device region 214 relative to a surface (e.g., the bottom surface) of the semiconductor substrate of the device region 214. For example, a depth (or height) of the trench capacitor structure 220b in the trench capacitor region 204b may be greater relative to a depth (or height) of the trench capacitor structure 220a in the trench capacitor region 204a. As another example, a depth (or height) of the trench capacitor structure 220c in the trench capacitor region 204c may be greater relative to the depth (or height) of the trench capacitor structure 220b in the trench capacitor region 204b, and may be greater relative to the depth (or height) of the trench capacitor structure 220a in the trench capacitor region 204a. In some implementations, the trench capacitor structures included in the same trench capacitor region may be formed to the same depth (or the same height). In some implementations, two or more trench capacitor structures included in the same trench capacitor region may be formed to different depths (or different heights).

The depths of the trench capacitor structures 220a-220c (and other trench capacitor structures in the trench capacitor regions 204a-204c) may be selected to provide sufficient capacitance so as to satisfy circuit decoupling parameters for the semiconductor devices 218 included in circuits of the semiconductor die package 200, while reducing the likelihood of warping, breaking, and/or cracking of the semiconductor die package 200. Some of the circuits of the semiconductor die package 200 may have greater decoupling capacitance requirements than other circuits in order to properly operate at desired performance parameters. Accordingly, deeper trench capacitor structures may be formed for these circuits relative to the depth of trench capacitor structures that are formed for other circuits that have lesser decoupling capacitance requirements. This enables a balance between satisfying capacitance requirements in the semiconductor die package 200 and reducing the likelihood of warpage in the semiconductor die package 200.

Additionally, and/or alternatively, the arrangement or layout of trench capacitor structure depths (or heights) across the semiconductor die package 200 may be determined or selected based on the overall floorplan of the first semiconductor die 202 and/or the second semiconductor die 206. For example, trench capacitor structures of greater depth (or greater height) may be included at or near an edge (e.g., an outer edge or an outer perimeter) of the first semiconductor die 202 and/or the second semiconductor die 206 to reduce the likelihood of warpage in the first semiconductor die 202 and/or the second semiconductor die 206. Trench capacitor structures of lesser depth (or lesser height) may be included closer to the center of the first semiconductor die 202 and/or the second semiconductor die 206. However, other arrangements of trench capacitor structure depths (or heights) across the semiconductor die package 200 may be selected to satisfy an equivalent series resistance (ESR) parameter for the interconnection regions 212 and 216, among other performance parameters.

Various design rules and/or principals may be employed when determining the arrangement or layout of trench capacitor structure depths (or heights) across the semiconductor die package 200. In some implementations, a target trench capacitor structure depth (or height) may be selected for the semiconductor die package 200, and the depths (or heights) of the trench capacitor structures across the semiconductor die package 200 may be selected within a particular range of the target trench capacitor structure depth (or height). As an example, a target trench capacitor structure depth (or height) may be selected for the semiconductor die package 200, and the depths (or heights) of the trench capacitor structures across the semiconductor die package 200 may be selected from a range of approximately +/−15% of the target trench capacitor structure depth (or height). However, other values for the range are within the scope of the present disclosure.

In some implementations, other parameters for the trench capacitor structures of the semiconductor die package 200 may be selected in a similar manner. For example, a target trench capacitor structure width (or critical dimension) may be selected for the semiconductor die package 200, and the widths (or critical dimensions) of the trench capacitor structures across the semiconductor die package 200 may be selected from a range of approximately +/−30% of the target trench capacitor structure width (or critical dimension). However, other values for the range are within the scope of the present disclosure.

As another example, a target trench capacitor structure aspect ratio (e.g., a ratio of the height to the width or a ratio of the width to the height) may be selected for the semiconductor die package 200, and the aspect ratios of the trench capacitor structures across the semiconductor die package 200 may be selected from a range of approximately +/−12% of the target trench capacitor structure aspect ratio. However, other values for the range are within the scope of the present disclosure.

The interconnect regions 212 and 216 may be referred to as back end of line (BEOL) regions. The interconnect region 212 may include one or more dielectric layers 222, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 222. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 212 may further include conductive layers 224 (e.g., conductive layers) in the one or more dielectric layers 222. The semiconductor devices 218 in the device region 210 may be electrically connected and/or physically connected with one or more of the conductive layers 224. The conductive layers 224 may include conductive lines, trenches, vias, pillars, interconnects, and/or another type of conductive layer.

Bond interface contact structures 226 may be included in the one or more dielectric layers 222 of the interconnect region 212. The bond interface contact structures 226 may be electrically connected and/or physically connected with one or more of the conductive layers 224. The bond interface contact structures 226 may include conductive terminals, conductive pads, conductive pillars, under bump metallization (UBM) structures, and/or another type of contacts. The conductive layers 224 and the bond interface contact structures 226 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

The interconnect region 216 may include one or more dielectric layers 228, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 228. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 216 may further include conductive layers 230 (e.g., a conductive layer 230a and a conductive layer 230b) in the one or more dielectric layers 228. The conductive layers 230 (e.g., conductive layers 230a and 230b) may include a metal material, conductive lines, trenches, vias, pillars, interconnects, and/or another type of conductive layers.

The interconnect region 216 may include a combination of contact structures, including electrode contact structures 232, substrate contact structures 234, interlayer contact structures 236, and/or bond interface contact structures 238. For example, the electrode contact structures 232 may electrically and/or physically connect electrode layers of the trench capacitor structures 220a-220c in the device region 214 with one or more of the conductive layers 230 (e.g., a portion of the conductive layer 230a). Additionally, or alternatively, the substrate contact structures 234 may electrically and/or physically connect a substrate of the device region 214 with one or more of the conductive layers 230 (e.g., a portion of the conductive layer 230a). Additionally, or alternatively, the interlayer contact structures 236 may electrically and/or physically connect one or more of the conductive layers 230 (e.g., portions of the conductive layer 230a and the conductive layer 230b). Additionally, or alternatively, the bond interface contact structures 238 may electrically and/or physically connect with the bond interface contact structures 226 of the second semiconductor die 206. The contact structures 232-238 may include vertical interconnect access structures (vias), conductive terminals, conductive pads, conductive pillars, UBM structures, and/or another type of contacts. The conductive layers 230 and the contact structures 232-238 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

As further shown in FIG. 2B, the semiconductor die package 200 may include a redistribution region 240. The redistribution region 240 may include a redistribution layer (RDL) structure, an interposer, a silicon-based interposer, a polymer-based interposer, and/or another type of redistribution structure. The redistribution region 240 may be configured to fan out and/or route signals and I/O of the semiconductor dies 202 and 206.

The redistribution region 240 may include one or more dielectric layers 242 and a plurality of conductive layers 244 disposed in the one or more dielectric layers 242. The dielectric layer(s) 242 may include polybenzoxazole (PBO), a polyimide, a low temperature polyimide (LTPI), an epoxy resin, an acrylic reason, a phenol resin, benzocyclobutene (BCB), one or more dielectric layers, and/or another suitable dielectric material.

The conductive layers 244 of the redistribution region 240 may include one or more materials, such as a gold (Au) material, a copper (Cu) material, a silver (Ag) material, a nickel (Ni) material, a tin (Sn) material, and/or a palladium (Pd) material, among other examples. The conductive layers 244 of the redistribution region 240 may include metal lines, vias, interconnects, and/or another type of conductive layers.

As further shown in FIG. 2B, the semiconductor die package 200 may include one or more backside through silicon via (BTSV) structures 246 through the device region 214, and into a portion of the interconnect region 216 of the first semiconductor die 202. The one or more BTSV structures 246 may include vertically elongated conductive structures (e.g., conductive pillars, conductive vias) that electrically connect one or more of the conductive layers 230 in the interconnect region 216 of the first semiconductor die 202 to one or more conductive layers 244 in the redistribution region 240. The one or more BTSV structures 246 may be referred to as through silicon via (TSV) structures in that the one or more BTSV structures 246 extend fully through a semiconductor substrate (e.g., a silicon substrate) of the device region 214 as opposed to extending fully through a dielectric layer or an insulator layer. The one or more BTSV structures 246 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

Under bump metallization (UBM) layers 248 may be included on a top surface of the one or more dielectric layers 242. The UBM layers 248 may be electrically connected and/or physically connected with one or more conductive layers 244 in the redistribution region 240. The UBM layers 248 may be included in recesses in the top surface of the one or more dielectric layers 242. The UBM layers 248 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

As further shown in FIG. 2B, the semiconductor die package 200 may include conductive terminals 250. The conductive terminals 250 may be electrically connected and/or physically connected with the UBM layers 248. The UBM layers 248 may be included to facilitate adhesion to the one or more conductive layers 244 in the redistribution region 240, and/or to provide increased structural rigidity for the conductive terminals 250 (e.g., by increasing the surface area to which the conductive terminals 250 are connected). The conductive terminals 250 may include ball grid array (BGA) balls, land grid array (LGA) pads, pin grid array (PGA) pins, and/or another type of conductive terminals. The conductive terminals 250 may enable the semiconductor die package 200 to be mounted to a circuit board, a socket (e.g., an LGA socket), an interposer or redistribution structure of a semiconductor die package (e.g., a chip on wafer on substrate CoWoS package, an integrated fanout (InFO) package), and/or another type of mounting structure.

In some implementations, the semiconductor die package 200 includes a seal ring structure 252. The seal ring structure 252 may be interspersed with one or more layers of the device region 210, the interconnect region 212, the device region 214, the interconnect region 216, and/or the redistribution region 240. The seal ring structure 252 provides for a physical barrier that substantially eliminates moisture and/or cracking from penetrating the first semiconductor die 202 and/or the second semiconductor die 206.

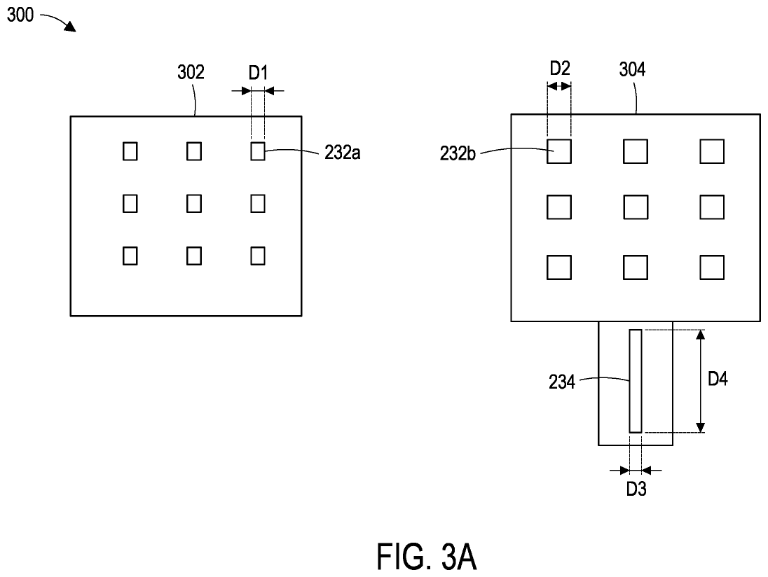

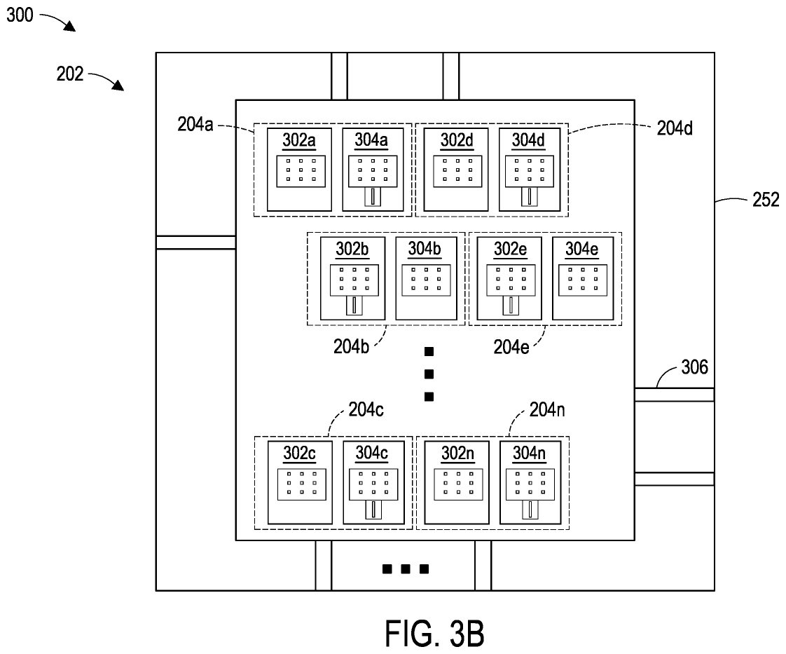

As described in greater detail in connection with FIGS. 3A-10, and elsewhere herein, formation of the first semiconductor die 202 may include using a wet clean operation to clean cavities used to form the interlayer contact structures 236. During the wet clean operation, a circuit that includes at least one of the electrode contact structures 232 and at least one of the substrate contact structures 234 may, in accordance with Kirchhoff's law, dissipate a charge that has accumulated from one or more of the trench capacitor structures 220a-220c. Dissipating the charge may reduce a likelihood of damage to a conductive layer (e.g., the conductive layer 230a) at an interface region 254. Reducing the likelihood of the damage to the conductive layer at the interface region 254 may reduce subsequent manufacturing defects during formation of the interlayer contact structures 236 (vertical interconnect access induced metal island corrosion (VIMIC) defects, among other examples). By decreasing the likelihood of such defects, a yield of the first semiconductor die 202 may increase to reduce an amount of resources needed to fabricate a volume of the first semiconductor die 202 and the semiconductor die package 200 (e.g., semiconductor manufacturing tools, raw materials, manpower, and/or computing resources).

As indicated above, FIGS. 2A and 2B are provided as an example. Other examples may differ from what is described with regard to FIGS. 2A and 2B.

FIGS. 3A and 3B are diagrams of an example implementation 300 of contact structures described herein. The implementation 300 may include the one or more of the electrode contact structures 232, the substrate contact structures 234, and/or the interlayer contact structures 236. In some implementations, a device (e.g., the semiconductor die package 200 including the second semiconductor die 206) may include aspects of the implementation 300 to mitigate VIMIC defects during formation one or more portions of the device.

FIG. 3A shows a top layout view of an example set of contact structures 302. The set of contact structures 302 includes at least one electrode contact structure 232a. In some implementations, the electrode contact structure 232a may include an approximately square cross-section. In some implementations, the electrode contact structure 232a may include an approximately round cross-section. In some implementations, the electrode contact structure 232a may include a different shaped cross-section, such as a rectangular cross-section. The electrode contact structure 232a may further include a width D1.

As an example, and in some implementations, the width D1 is included in a range of approximately 0.117 microns to approximately 0.143 microns. If the width D1 is less than approximately 0.117 microns or greater than approximately 0.143 microns, an electrical resistivity or impedance associated with the electrode contact structure 232a may not satisfy a threshold sufficient for an electrical circuit (including the electrode contact structure 232a) to generate a voltage drop that reduces a likelihood of damage to a semiconductor die (e.g., the second semiconductor die 206), during formation of the semiconductor die. However, other values and ranges for the width D1 are within the scope of the present disclosure.

FIG. 3A further shows a top layout view of an example set of contact structures 304. The set of contact structures 304 includes at least one electrode contact structure 232b. In some implementations, the electrode contact structure 232b may include an approximately square cross-section. In some implementations, the electrode contact structure 232b may include an approximately round cross-section. In some implementations, the electrode contact structure 232b may include a different shaped cross-section, such as a rectangular cross-section. The electrode contact structure 232b may further include a width D2.

The width D2 may be greater relative to the width D1. As an example, and in some implementations, the width D2 is included in a range of approximately 0.162 microns to approximately 0.188 microns. If the width D2 is less than approximately 0.162 microns or greater than approximately 0.188 microns, an electrical resistivity or impedance associated with the electrode contact structure 232b may not satisfy a threshold sufficient for an electrical circuit (including the electrode contact structure 232b) to generate a voltage drop that reduces a likelihood of damage to a semiconductor die (e.g., the second semiconductor die 206) during formation of the semiconductor die. However, other values and ranges for the width D2 are within the scope of the present disclosure.

The set of contact structures 304 may further include at least one substrate contact structure 234. In some implementations, the substrate contact structure 234 may include an approximately rectangular cross-section. In some implementations, the substrate contact structure 234 may include an approximately elliptical cross-section. In some implementations, the substrate contact structure 234 may include a different shaped cross-section. The substrate contact structure 234 may further include a width D3 and a length D4.

As an example, the width D3 may be included in a range of approximately 0.117 microns to approximately 0.143 microns. If the width D3 is less than approximately 0.117 microns or greater than approximately 0.143 microns, an electrical resistivity or impedance associated with the substrate contact structure 234 may not satisfy a threshold sufficient for an electrical circuit (including the substrate contact structure 234) to generate a voltage drop that reduces a likelihood of damage to a semiconductor die (e.g., the second semiconductor die 206) during formation of the semiconductor die. However, other values and ranges for the width D3 are within the scope of the present disclosure.

Further, and as an example, the length D4 may be include in a range of approximately 2.61 microns to approximately 3.19 microns. If the length D4 is less than approximately 2.61 microns or greater than 3.19 microns, an electrical resistivity or impedance associated with the substrate contact structure 234 may not satisfy a threshold sufficient for an electrical circuit (including the substrate contact structure) to generate a voltage drop that reduces a likelihood of damage to a semiconductor die (e.g., the second semiconductor die 206) during formation of the semiconductor die. However, other values and ranges for the length D4 are within the scope of the present disclosure.

In some implementations, a ratio of a cross-sectional area of the electrode contact structure 232b to a cross-sectional area of the electrode contact structure 232a may be included in a range of approximately 19:10 to approximately 21:10. If the ratio is less than approximately 19:10 or greater than approximately 21:10, electrical resistivities or impedances associated with the electrode contact structure 232a and/or the electrode contact structure 232b may not satisfy thresholds sufficient for an electrical circuit (including electrode contact structures 232a and 232b) to generate a voltage drop that reduces a likelihood of damage to a semiconductor die (e.g., the second semiconductor die 206) during formation of the semiconductor die. However, other values and ranges for the ratio of the cross-sectional area of the electrode contact structure 232b to the cross-sectional area of the electrode contact structure 232a are within the scope of the present disclosure.

In some implementations, a ratio of a cross-sectional area of the substrate contact structure 234 to a cross-sectional area of the electrode contact structure 232a may be included in a range of approximately 18:1 to approximately 22:1 If the ratio is less than approximately 18:1 or greater than approximately 22:1, electrical resistivities or impedances associated with the electrode contact structure 232a and/or the substrate contact structure 234 may not satisfy thresholds sufficient for an electrical circuit (including electrode contact structure 232a and the substrate contact structure 234) to generate a voltage drop that reduces a likelihood of damage to a semiconductor die (e.g., the second semiconductor die 206) during formation of the semiconductor die. However, other values and ranges for the ratio of the cross-sectional area of the substrate contact structure 234 to the cross-sectional area of the electrode contact structure 232a are within the scope of the present disclosure.

In some implementations, the top layout views of the sets of contact structures 302 and 304 correspond to layouts (e.g., masking patterns) of photolithography masks used in conjunction with the exposure tool 104 of FIG. 1 to form the sets of contact structures 302 and/or 304. In some implementations, the layouts make be combined onto a single photolithography mask.

FIG. 3B shows an example top view of the second semiconductor die 206 including an example layout of the sets of contact structures 302a-302n and 304a-304n. As shown in FIG. 3B, the sets of contact structures 302a-302n and 304a-304n are shown positioned relative (e.g., over) the capacitor regions 204a-204n of FIG. 2A.

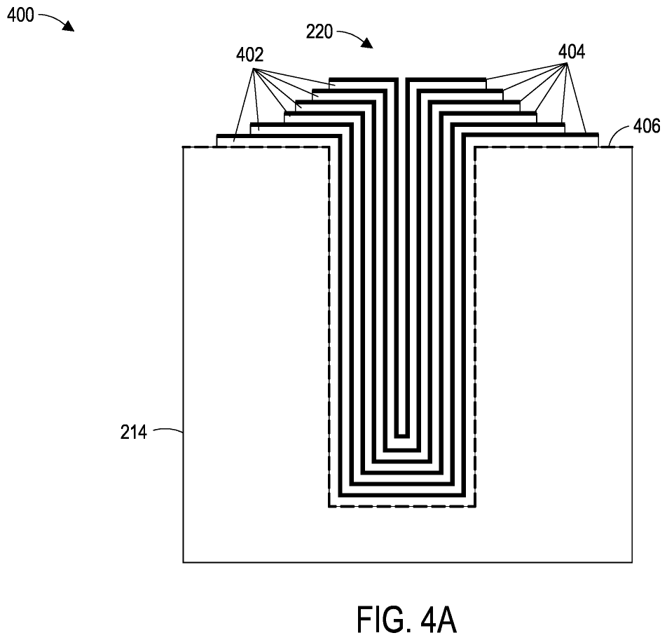

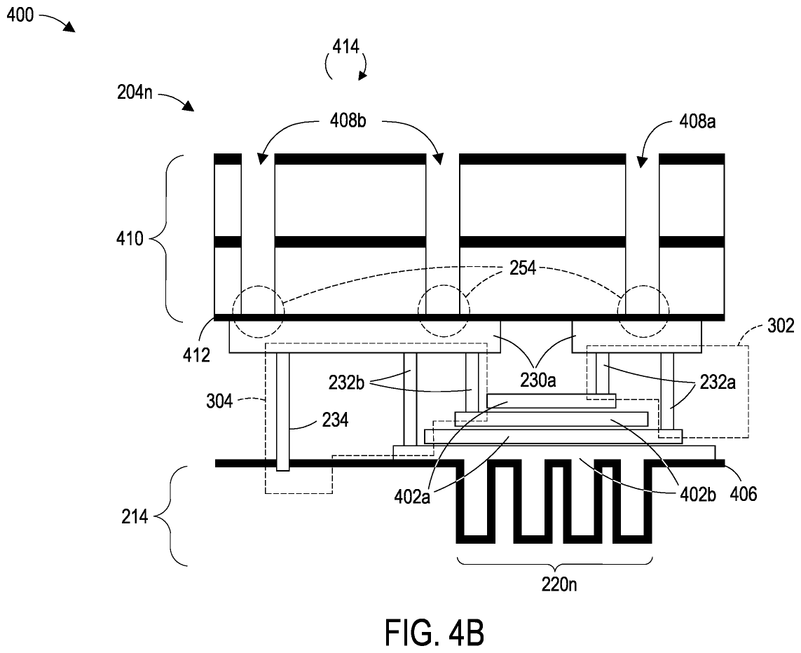

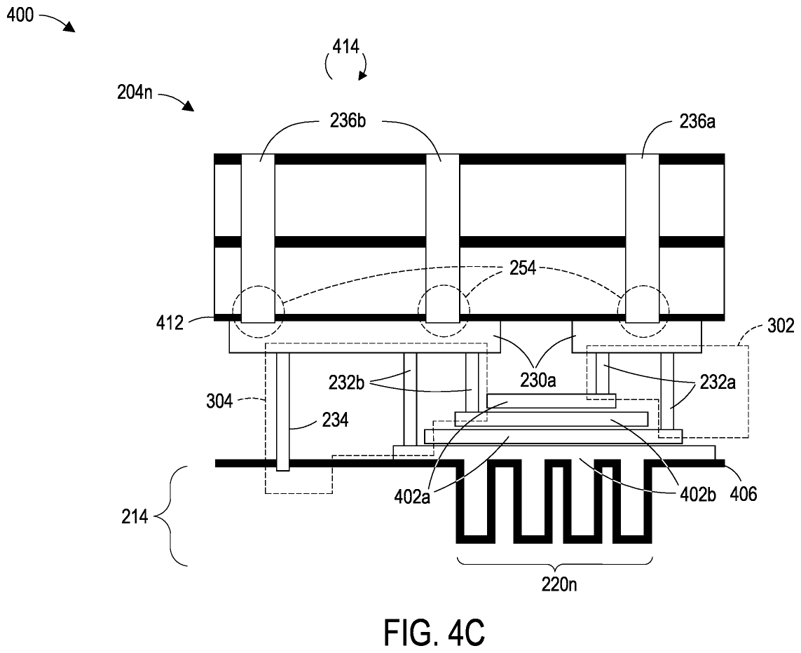

As described in greater detail in connection with FIGS. 4A-4C, and elsewhere herein, the sets of contact structures 302a-302n may include contact structures (e.g., the electrode contact structure(s) 232a) that connect with ground voltage electrode layers (e.g., V_{dd} electrode layers) of corresponding capacitor structures (e.g., corresponding trench capacitor structure(s) 220) within the capacitor regions 203a-204n.

Further, and as described in greater detail in connection with FIGS. 4A-4C and elsewhere herein, the sets of contact structures 304a-304n may include contact structures (e.g., the electrode contact structure(s) 232b) that connect with source voltage layers (e.g., V_{dd} electrode layers) of corresponding capacitor structures (e.g., corresponding trench capacitor structure(s) 220) within the capacitor regions 203a-204n. Additionally, or alternatively, the sets of contact structures 304a-304n may include contact structures (e.g., the substrate contact structure(s) 234) that connect with the substrate of the second semiconductor die 206.

In some implementations, and as shown in FIG. 3B, the second semiconductor die 206 includes seal ring contact structures 306. The seal ring contact structures 306 (e.g., which may correspond to portions of the conductive layers 230 of FIG. 2B) may connect at least one of the sets of contact structures 304a-304n with the seal ring structure 252.

As indicated above, FIGS. 3A and 3B are provided as an example. Other examples may differ from what is described with regard to FIGS. 3A and 3B.

FIGS. 4A-4C are diagrams of an example implementation 400 of a trench capacitor structure described herein. The implementation 400 includes example configurations of the trench capacitor structure 220 in relation to the electrode contact structures 232a, the electrode contact structures 232b, an/or the substrate contact structures 234.

As shown in FIG. 4A, the trench capacitor structure 220 may be formed in the device region 214. The trench capacitor structure 220 may include a plurality of conductive layers 402 (e.g., electrode layers) and a plurality of dielectric layers 404. The conductive layers 402 and the dielectric layers 404 may be arranged in an alternating configuration in the trench capacitor structure 220. For example, a first conductive layer 402 may be included in the trench capacitor structure 220, a first dielectric layer 404 may be included over the first conductive layer 402, a second conductive layer 402 may be included over the first dielectric layer 404, and so on. A dielectric layer 404 between a pair of conductive layers 402 may correspond to a trench capacitor of the trench capacitor structure 220, where the conductive layers 402 correspond to the electrodes of the trench capacitor and the dielectric layer 404 corresponds to the dielectric medium of the trench capacitor. In this way, the trench capacitor structure 220 includes a plurality of layered trench capacitors that extend into the semiconductor substrate of the device region 214.

In general, a deeper trench capacitor structure 220 may provide a greater amount of decoupling capacitance relative to a shallower trench capacitor structure 220. Additionally. and/or alternatively, a wider trench capacitor structure 220 may include a greater quantity of conductive layers 402 and a greater quantity of dielectric layers 404 and, therefore, a greater quantity of trench capacitors relative to a narrower trench capacitor structure 220. This enables a wider trench capacitor structure 220 to also provide a greater amount of capacitance relative to a narrower trench capacitor structure 220.

The conductive layers 402 may include one or more conductive materials, such as a conductive metal (e.g., copper (Cu), tungsten (W), titanium (Ti), tantalum (Ta), ruthenium (Ru), cobalt (Co)), a conductive ceramic (e.g., tantalum nitride (TaN), titanium nitride (TiN)), and/or another type of conductive material. The dielectric layers 404 may include one or more dielectric materials such as an oxide (e.g., silicon oxide (SiOₓ)), a nitride (e.g., silicon nitride (SiₓN_{y}), and/or another suitable dielectric material.

As further shown in FIG. 4A, the conductive layers 402 and the dielectric layers 404 may partially extend out of the semiconductor substrate of the device region 214 and may extend along a portion of the surface of the semiconductor substrate of the device region 214. This enables conductive terminals to be electrically connected and/or physically connected with the conductive layers 402. In some implementations, the trench capacitor structure 220 may further include a liner layer 406. The liner layer 406 may include a dielectric material, such a silicon oxide material (SiO₂) or a silicon nitride material (SiN), among other examples.

FIG. 4B shows a side view of a trench capacitor region (e.g., the trench capacitor region 204n in a partially formed state) including the trench capacitor structure 220n. One or more of the semiconductor processing tools 102-114 and/or the wafer/die transport tool 116 may perform photolithography patterning operations, deposition operations, etching operations, CMP operations, and/or another type of operations as part of forming the trench capacitor region 204n.

As shown in FIG. 4B, the trench capacitor structure 220n includes the conductive layers 402a interspersed with the conductive layers 402b. In some implementations, the conductive layers 402a correspond to V_{dd} (e.g., ground voltage) electrode layers of the trench capacitor structure 220n. In some implementations, the conductive layers 402b correspond to Vₛₛ (e.g., source voltage) electrode layers of the trench capacitor structure 220n.

As shown in FIG. 4B, the set of contact structures 302 includes the electrode contact structures 232a that electrically and/or physically connect the conductive layers 402a (e.g., V_{dd} electrode layers) and a portion of the conductive layer 230a. As further shown in FIG. 4B, the set of contact structures 304 includes the electrode contact structures 232b that electrically and/or physically connect the conductive layers 402b (e.g., Vₛₛ electrode layers) to a portion of the conductive layer 230a. Additionally, or alternatively, the electrode contact structures 232b may electrically and/or physically connect the conductive layers 402b (e.g., Vₛₛ electrode layers) to a portion of another conductive layer.

Additionally, or alternatively and as shown in FIG. 4B, the set of contact structures 304 includes the substrate contact structure that electrically and/or physically connects the substrate of the device region 214 with the same portion of the conductive layer 230a that connects with the conductive layers 402b via the electrode contact structures 232b.

As part of forming the trench capacitor region 204n, additional contact structures (e.g., the interlayer contact structures 236) may be subsequently formed to provide connectivity to additional conductive layers that ultimately connect the trench capacitor structure 220n with a ground voltage and/or a source voltage.

Forming the additional contact structures may include forming sets of cavities 408 (e.g., the sets of cavities 408a and 408b) in one or more layers 410 (e.g., one or more conductive layers and/or dielectric layers) above the conductive layer 230a. In some implementations, the one or more layers 410 include an etch stop layer 412 (e.g., a layer of a silicon nitride (SiN) material).

In some implementations, a pattern in a photoresist layer is used to etch the one or more layers 410 to form the sets of cavities 408. In these implementations, the deposition tool 102 forms the photoresist layer on the one or more layers 410. The exposure tool 104 exposes the photoresist layer to a radiation source to pattern the photoresist layer. The developer tool 106 develops and removes portions of the photoresist layer to expose the pattern. The etch tool 108 etches the sets of cavities 408a and 408b based on the pattern to form the sets of cavities 408a and 408b in the one or more layers 410. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the sets of cavities 408a and 408b based on a pattern. In some implementations, a photoresist removal tool removes the remaining portions of the photoresist layer (e.g., using a chemical stripper, plasma ashing, and/or another technique). In some implementations, the etch operation may result in an uneven etching that weakens portions of the etch stop layer 412 and/or the the conductive layer 230a to make the portions of the etch stop layer 412 and/or the conductive layer 230a susceptible to damage. Additionally, or alternatively, the etch operation may induce an electrical charge buildup within the interface regions 254 at the bottom of the sets of cavities 408a and 408b.

Forming the sets of cavities 408a and 408b may further include performing a wet clean operation 414. The wet clean operation 414 may include, for example, one or more rinse and spin operations (e.g., using residue remover solutions and/or de-ionized water solutions) followed by a dry spin operation. In some implementations, the wet clean operation 414 may cause an electrical charge buildup within the trench capacitor structure 220n.

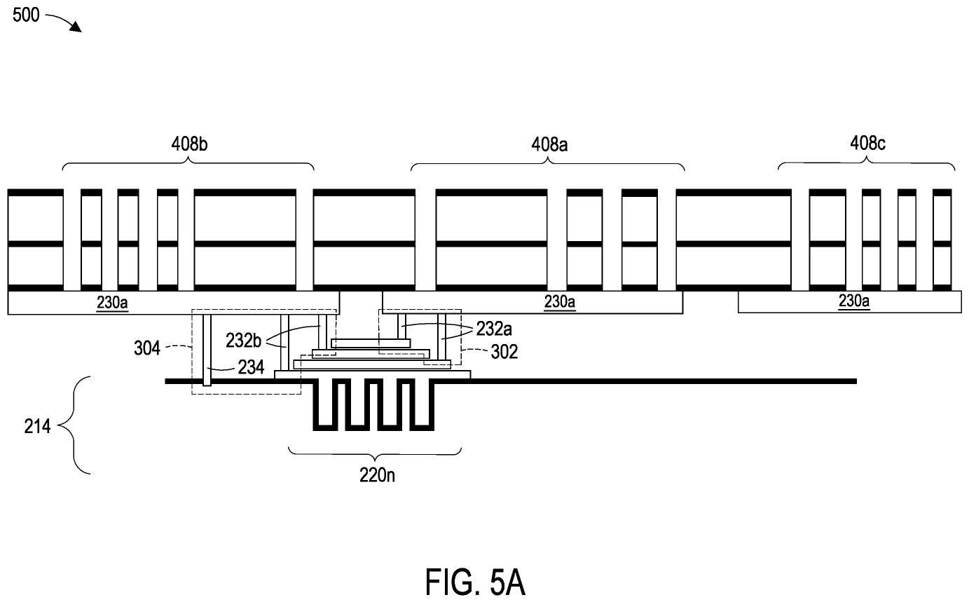

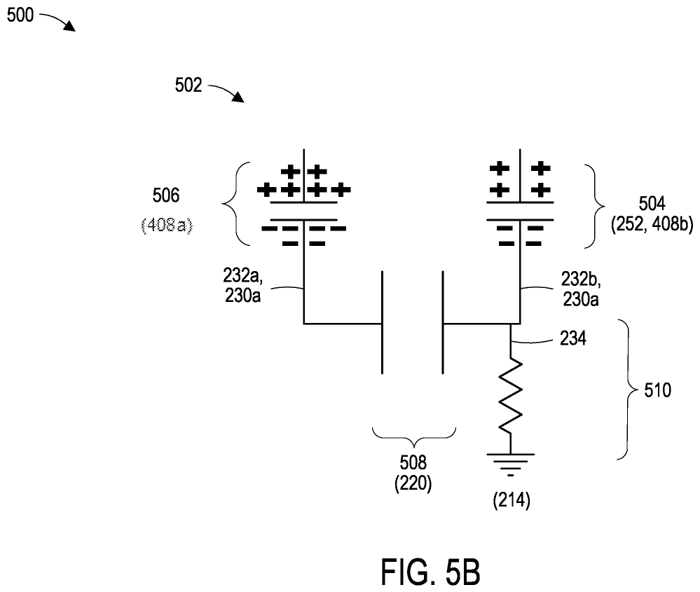

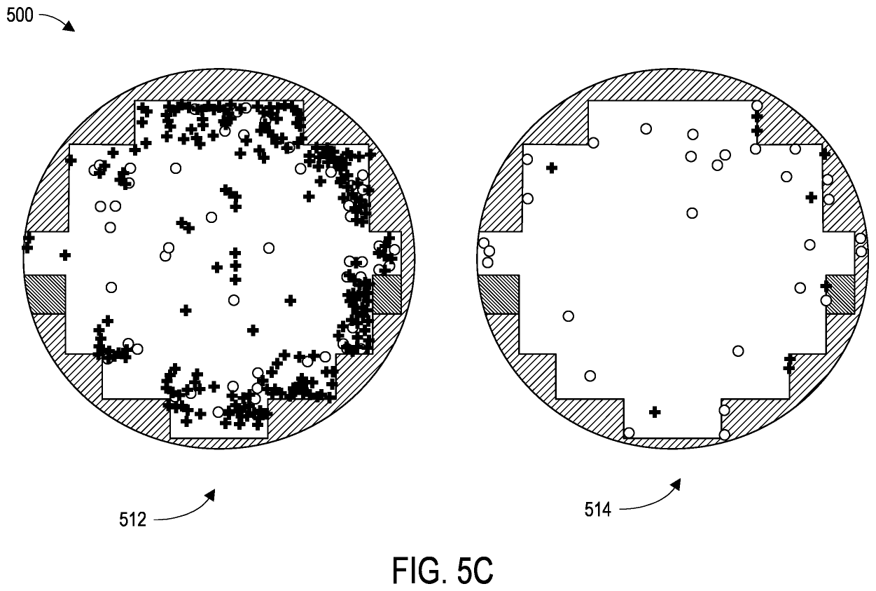

As described in greater detail in connection with FIGS. 5A-5C, and elsewhere herein, the sets of contact structures 302 and 304 form an electrical circuit that mitigates a discharge of electrical charge buildup within the trench capacitor structure 220n that, in combination with the electrical charge buildup within the interface regions 254, may cause additional damage to the etch stop layer 412 and/or extrusions within the conductive layer 230a.

FIG. 4C shows details related to formation of the interlayer contact structures 236a and 236b. In some implementations, the interlayer contact structures 236a and 236b correspond to vertical interconnect access structures that provide further electrical and/or physical connectivity between the conductive layers 402a and 402b of the trench capacitor structure 220n, respectively, to a ground voltage and a source voltage.

In FIG. 4C, portions of the etch stop layer 412 at the bottom of the sets of cavities 408a and 408b may have been removed by an additional etching operation. To form the interlayer contact structures 236a and 236b (e.g., V_{dd} and Vₛₛ vias, respectively), the deposition tool 102 and/or the plating tool 112 may fill the sets of cavities 408a and 408b in a CVD operation, a PVD operation, an ALD operation, an electroplating operation, another deposition operation described above in connection with FIG. 1, and/or another suitable deposition operation. In some implementations, the planarization tool 110 planarizes the interlayer contact structures 236a and 236b after the deposition tool 102 and/or the plating tool 112 fills the sets of cavities 408a and 408b. During formation of the interlayer contact structures 236a and 236b, a likelihood of VIMIC defects in the interface regions 254 may be substantially reduced (e.g., due to the mitigation of an electrical discharge from the trench capacitor structure 220n in the preceding wet clean operation 414).

As indicated above, FIGS. 4A-4C provided as an example. Other examples may differ from what is described with regard to FIGS. 4A-4C.

As shown in FIGS. 3A, 3B, 4A, 4B, and 4C, and as described elsewhere herein, a device (e.g., the second semiconductor die 206) includes a trench capacitor structure (e.g., the trench capacitor structure 220). The trench capacitor structure includes a first set of electrode layers (e.g., the conductive layers 402a) corresponding to a first voltage polarity (e.g., V_{dd}) and a second set of electrode layers (e.g., the conductive layers 402b) corresponding to a second voltage polarity (e.g., Vₛₛ), where the second voltage polarity is different from the first voltage polarity. The device includes a first set of contact structures (e.g., the set of contact structures 302) including a first subset of electrode contact structures (e.g., the electrode contact structures 232a) that each has a first cross-sectional area and that connect the first set of electrode layers with a portion of a first conductive layer (e.g., a portion of the conductive layer 230a). The device includes a second set of contact structures (e.g., the set of contact structures 304) including a second subset of electrode contact structures (e.g., the electrode contact structures 232b) that each has a second cross-sectional area and that connect the second set of electrode layers with a portion of a second conductive layer (e.g., a layer which may be other than the conductive layer 230a), where the second cross-sectional area is greater relative to the first cross-sectional area. In some implementations, the first conductive layer and the second conductive layer are a same conductive layer.

Additionally, or alternatively, the device (e.g., the second semiconductor die 206) includes a capacitor structure (e.g., the trench capacitor structure 220). The device includes a first interlayer contact structure associated with a ground voltage (e.g., the interlayer contact structure 236a) for the capacitor structure. The device includes a second interlayer contact structure associated with a source voltage (e.g., the interlayer contact structure 236b) for the capacitor structure. The device includes a first electrode contact structure having a first cross-sectional area (e.g., the electrode contact structure 232a) and connecting the first interlayer contact structure with a ground voltage electrode layer (e.g., the conductive layer 402a) of the capacitor structure. The device includes a second electrode contact structure (e.g., the electrode contact structure 232b) having a second cross-sectional area and connecting the second interlayer contact structure with a source voltage electrode layer (e.g., the conductive layer 402b) of the capacitor structure, where the second cross-sectional area is greater relative to the first cross-sectional area.

FIGS. 5A-5C are diagrams of an example implementation 500 of wafer-based substrate described herein. The wafer-based substrate may correspond to a semiconductor substrate (e.g., a 300 millimeter diameter silicon substrate having an approximately round shape) including the device region 214. Further, the implementation 500 may include the trench capacitor structure 220, the sets of contact structures 302, and/or the set of contact structures 304.

FIG. 5A shows sets of cavities 408a, 408b, and 408c over respective regions of the conductive layer 230a. In FIG. 5A, the set of cavities 408a may be for subsequent formation of interlayer contact structures (e.g., the interlayer contact structures 236a that provide intermediate connections of a ground voltage (V_{dd}) to a portion of the conductive layer 230a). Further, and as shown in FIG. 5A, the set of cavities 408b may be for subsequent formation of interlayer contact structures (e.g., the interlayer contact structures 236b that provide intermediate connections of a source voltage (Vₛₛ) to a portion of the conductive layer 230a).

As further shown in FIG. 5A, the set of cavities 408c may be for subsequent formation of additional interlayer contact structures that connect to a portion of the conductive layer 230a. However, such additional interlayer contact structures may not be included in the electrical circuit that may charge and/or discharge the trench capacitor structure 220.

FIG. 5B shows an example electrical circuit 502 including the trench capacitor structure 220, the conductive layer 230a, and the seal ring structure 252. As shown, the cavities 408a and/or 408b include electrical potentials (e.g., electrical potentials 504 and 506, respectively) because of the etching operation described in connection with FIG. 4B. As shown in FIG. 5B, the seal ring structure 252 and the conductive layer 230a (e.g., Vₛₛ) may be electrically coupled.

As further shown in FIG. 5B, the cavities 408 and/or 408b electrically couple to the trench capacitor structure 220 using the electrode contact structures 232a and 232b and the conductive layer 230a. Additionally, and as shown in FIG. 5B, the substrate contact structure 234 may electrically couple the electrical circuit 502 to the substrate of the device region 214.

During a wet clean operation (e.g., the wet clean operation 414 of FIG. 4B), the trench capacitor structure 220 may accumulate an electrical potential 508. However, based on the substrate contact structure 234 that electrically couples the electrical circuit 502 to the substrate of the device region 214, a voltage drop 510 (e.g., a difference in an electrical potential between the cavities 408a and/or 408b and the substrate of the device region 214) may occur that inhibits a discharge of the electrical potential 508 from the trench capacitor structure 220 into the cavities 408a and/or 408b (e.g., into the cavities 408a and/or 408b at the interface regions 254). By inhibiting the discharge of the electrical potential 508 into the cavities 408a and/or 408b, a superposition of electrical potentials (e.g., the electrical potential 508 combining with the electrical potential 504 and/or the electrical potential 506) may be avoided to reduce a likelihood of damage (e.g., extrusions of the conductive layer 230a, sometimes referred to as “Hillocks”).

Within the electrical circuit 502, the voltage drop 510 may correspond to a voltage divider effect that complies with Kirchhoff's law. Such a voltage divider effect may be based on a cross-sectional area of the substrate contact structure 234 in relation to cross-sectional areas of the electrode contact structures 232a and 232b (e.g., as described in connection with FIG. 3A).

FIG. 5C shows an example comparison of defect distributions across a wafer-based substrate. In FIG. 5C, example 512 may correspond to a wafer-based substrate (e.g., a silicon semiconductor wafer) including multiples of a semiconductor die not including configurations of the electrode contact structures 232, the substrate contact structures 234, and/or the interlayer contact structures 236 described in connection with 5A, 5B, and elsewhere herein. In contrast, example 514 may correspond to a wafer-based substrate including multiples of a semiconductor die that includes configurations of the electrode contact structures 232, the substrate contact structures 234, and/or the interlayer contact structures 236.

In some implementations, and as shown in example 512, a defect density may increase near a perimeter of the wafer-based substrate due to electrical potentials within trench capacitors near the perimeter (e.g. the trench capacitor structure(s) 220) that increase during a wet clean operation (e.g., during a wet clean operation of the cavities 408 that includes a spinning of the wafer-based substrate, where a localized velocity near a perimeter may be greater relative to a localized velocity near a center and cause additional charge buildups within the trench capacitors structure(s) 220 near the perimeter). However, and as shown in example 514, a defect distribution (e.g., an amount of VIMIC defects across the wafer-based substrate and/or a defect density near a perimeter of the wafer-based substrate) is substantially lesser relative to a defect distribution in the example 512.

As shown in FIG. 5C, a likelihood of VIMIC defects within the wafer-based substrate (e.g., VIMIC defects within semiconductor dies) may decrease due to the semiconductor dies including the substrate contact structures 234 and the electrode contact structures 232a and 232b. By decreasing the likelihood of such defects, a yield of the semiconductor dies may increase to reduce an amount of resources needed to fabricate a volume of the semiconductor dies (e.g., semiconductor manufacturing tools, raw materials, manpower, and/or computing resources).

As indicated above, FIGS. 5A-5C provided as examples. Other examples may differ from what is described with regard to FIGS. 5A-5C.

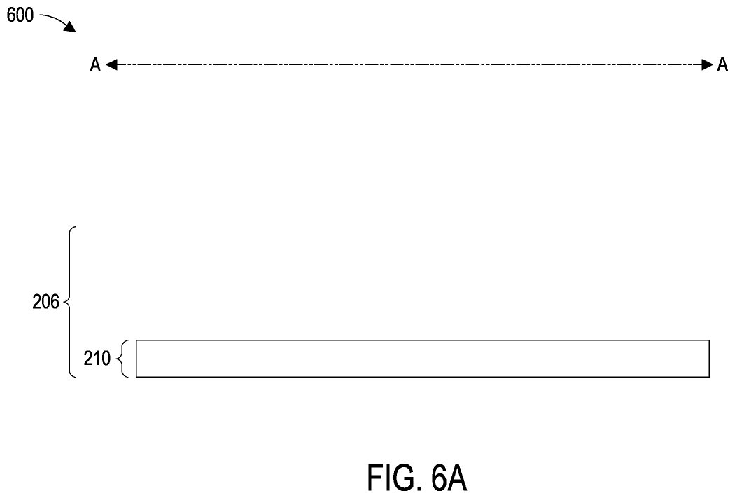

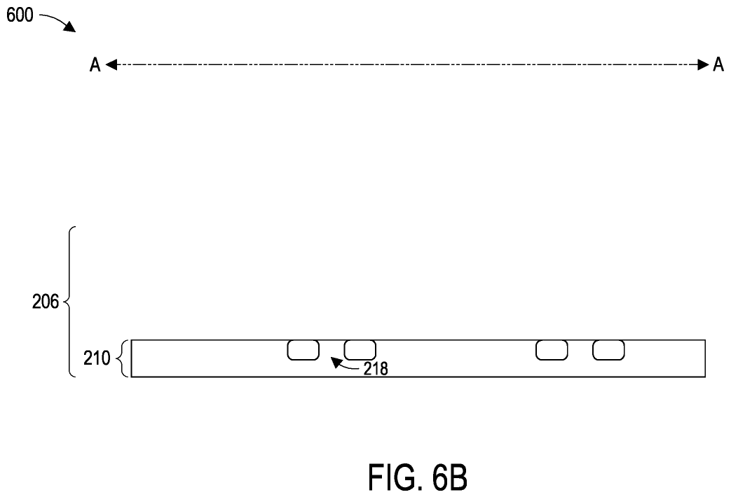

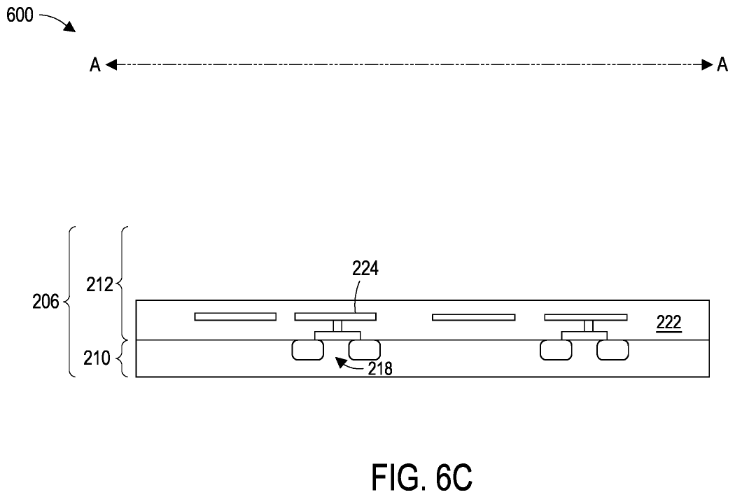

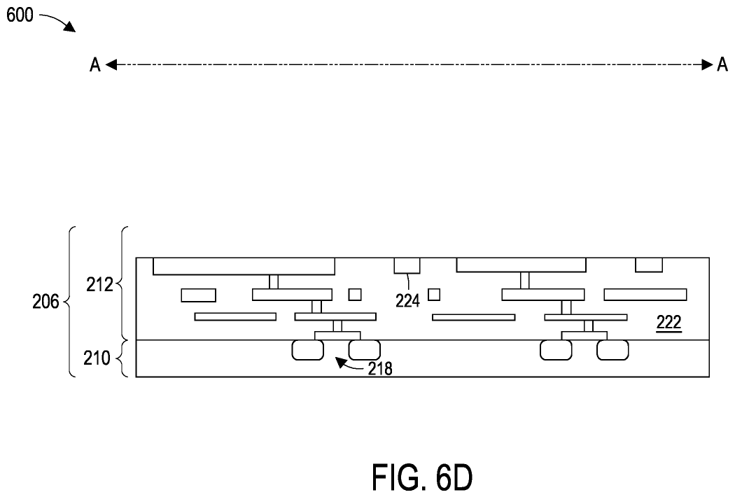

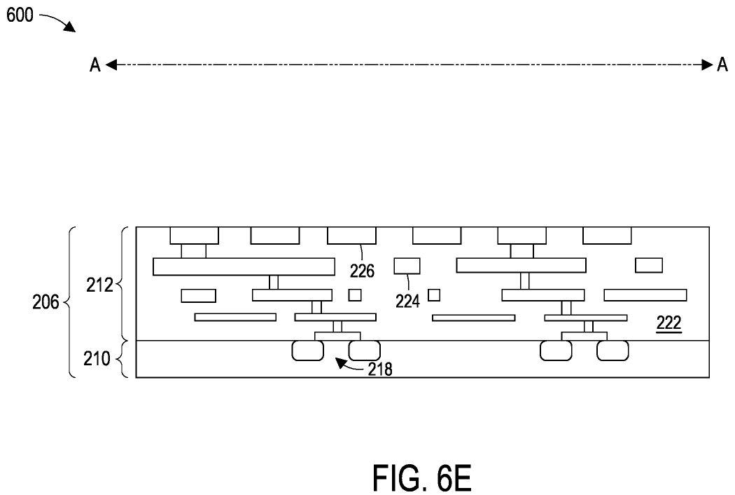

FIGS. 6A-6E are diagrams of an example implementation 600 of forming a semiconductor die described herein. In some implementations, the example implementation 600 includes an example process for forming a portion of the second semiconductor die 206. In some implementations, one or more of the semiconductor processing tools 102-114 and/or the wafer/die transport tool 116 may perform one or more of the operations described in connection with the example implementation 600. In some implementations, one or more operations described in connection with the example implementation 600 may be performed by another semiconductor processing tool.

Turning to FIG. 6A, one or more of the operations in the example implementation 600 may be performed in connection with the semiconductor substrate of the device region 210 of the second semiconductor die 206. The semiconductor substrate of the device region 210 may be provided in the form of a semiconductor wafer or another type of substrate.

As shown in FIG. 6B, one or more semiconductor devices 218 may be formed in the device region 210. For example, one or more of the semiconductor processing tools 102-114 may perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor dies of another type. In some implementations, one or more regions of the semiconductor substrate of the device region 210 may be doped in an ion implantation operation to form one or more p-wells, one or more n-wells, and/or one or more deep n-wells. In some implementations, the deposition tool 102 may deposit one or more source/drain regions, one or more gate structures, and/or one or more STI regions, among other examples.

As shown in FIGS. 6C-6E, the interconnect region 212 of the second semiconductor die 206 may be formed over and/or on the semiconductor substrate of the device region 210. One or more of the semiconductor processing tools 102-114 may form the interconnect region 212 by forming one or more dielectric layers 222 and forming a plurality of conductive layers 224 in the plurality of dielectric layers 222. For example, the deposition tool 102 may deposit a first layer of the one or more dielectric layers 222 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of conductive layers 224 in the recesses (e.g., using a CVD technique, an ALD technique, a PVD technique, an electroplating technique, and/or another type of deposition technique). At least a portion of the first metallization layer may be electrically connected and/or physically connected with the semiconductor devices 218. The deposition tool 102, the etch tool 108, the plating tool 112, and/or another semiconductor processing tool may continue to perform similar processing operations to forming the interconnect region 212 until a sufficient or desired arrangement of conductive layers 224 is achieved.

As shown in FIG. 6E, one or more of the semiconductor processing tools 102-114 may form another layer of the one or more dielectric layers 222 and may form a plurality of the bond interface contact structures 226 in the layer such that the bond interface contact structures 226 are electrically connected and/or physically connected with one or more of the conductive layers 224. For example, the deposition tool 102 may deposit the layer of the one or more dielectric layers 222 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the bond interface contact structures 226 in the recesses (e.g., using a CVD technique, an ALD technique, a PVD technique, an electroplating technique, and/or another type of deposition technique).

As indicated above, FIGS. 6A-6E are provided as an example. Other examples may differ from what is described with regard to FIGS. 6A-6E.

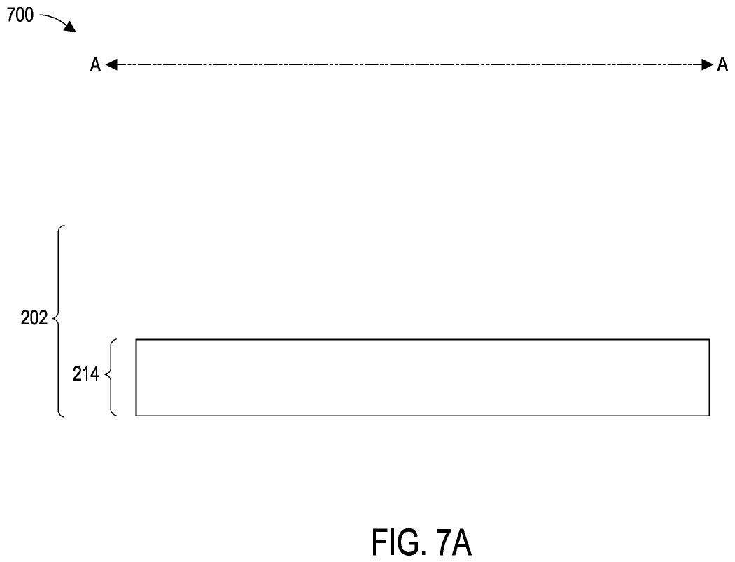

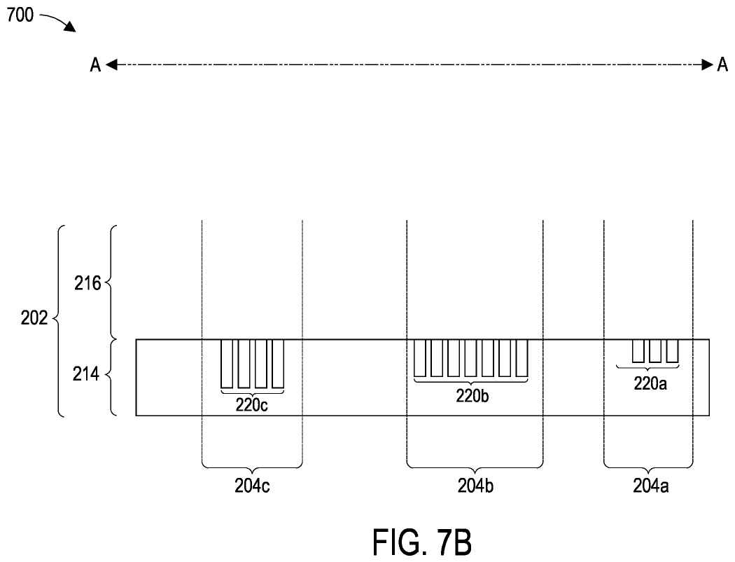

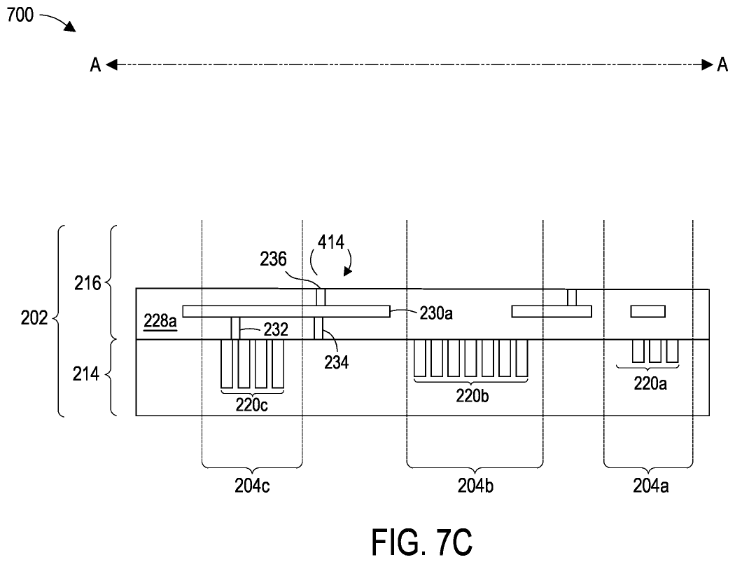

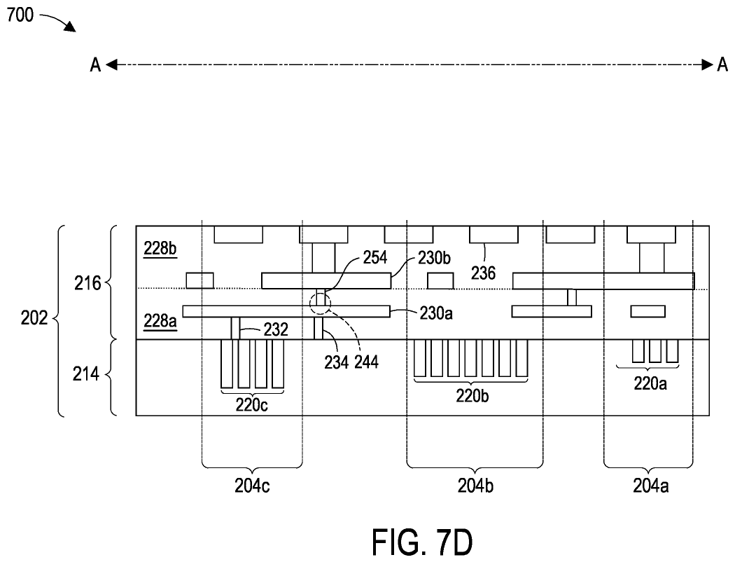

FIGS. 7A-7D are diagrams of an example implementation 700 of forming a semiconductor die described herein. In some implementations, the example implementation 700 includes an example process for forming a portion of the first semiconductor die 202. In some implementations, one or more of the semiconductor processing tools 102-114 and/or the wafer/die transport tool 116 may perform one or more of the operations described in connection with the example implementation 700. In some implementations, one or more operations described in connection with the example implementation 700 may be performed by another semiconductor processing tool.

Turning to FIG. 7A, one or more of the operations in the example implementation 700 may be performed in connection with the semiconductor substrate of the device region 214 of the first semiconductor die 202. The semiconductor substrate of the device region 214 may be provided in the form of a semiconductor wafer or another type of substrate.

As shown in FIG. 7B, a plurality of trench capacitor structures may be formed in the device region 214. Respective pluralities of trench capacitor structures may be formed in each of a plurality of trench capacitor regions in the device region 214.

As an example of the above, one or more of the semiconductor processing tools 102-114 may perform photolithography patterning operations, etching operations, deposition operations, CMP operations, and/or another type of operations to form a trench capacitor structure 220a in a trench capacitor region 204a of the device region 214, a trench capacitor structure 220b in a trench capacitor region 204b of the device region 214, and a trench capacitor structure 220c in a trench capacitor region 204c of the device region 214.

To form a trench capacitor structure, a recess may be formed in the semiconductor substrate of the device region 214 using a pattern in a photoresist layer, a hard mask, and/or another type of masking layer. For example, the deposition tool 102 forms a photoresist layer over the semiconductor substrate of the device region 214. The exposure tool 104 exposes the photoresist layer to a radiation source to pattern the photoresist layer. The developer tool 106 develops and removes portions of the photoresist layer to expose the pattern. The etch tool 108 etches into the semiconductor substrate of the device region 214 to form the recess. As described in connection with FIG. 4A, the deposition tool 102 may perform a deposition operation (e.g., a CVD operation, a PVD operation, an ALD operation) to deposit a first conductive layer 402 (e.g., an electrode layer) in the recess such that the first conductive layer 402 conforms to the shape of the recess. The deposition tool 102 may perform a deposition operation (e.g., a CVD operation, a PVD operation, an ALD operation) to deposit a first dielectric layer 404 on the first conductive layer 402. The deposition tool 102 may perform a deposition operation (e.g., a CVD operation, a PVD operation, an ALD operation) to deposit a second conductive layer 402 on the first dielectric layer 404. The deposition tool 102 may perform a deposition operation (e.g., a CVD operation, a PVD operation, an ALD operation) to deposit a second dielectric layer 404 on the second conductive layer 402. The deposition tool 102 may perform subsequent deposition operations until a sufficient or desired quantity of deep trench capacitors are formed in the recess for the deep trench capacitor structure.

As shown in FIG. 7C, the interconnect region 216 of the first semiconductor die 202 may be formed over and/or on the semiconductor substrate of the device region 214. One or more of the semiconductor processing tools 102-114 may form the interconnect region 216 by forming the dielectric layers 228a and forming the electrode contact structures 232, the substrate contact structures 234, the conductive layer 230a, and the interlayer contact structures 236 in the dielectric layers 228a. The deposition tool 102 may deposit the dielectric layers 228a (e.g., using a CVD technique, an ALD technique, a PVD technique, and/or another type of deposition technique). The deposition tool 102 and/or the plating tool 112 may form the conductive layer 230a (e.g., using a CVD technique, an ALD technique, a PVD technique, an electroplating technique, and/or another type of deposition technique).

As described in greater detail in connection with FIGS. 4B and 4C, the etch tool 108 may remove portions of the one or more dielectric layers 228a to form cavities (e.g., the sets of cavities 408). Further, as part of forming the cavities, a cleaning tool may perform the wet clean operation 414. The deposition tool 102 and/or the plating tool 102 may further form the electrode contact structures 232, the substrate contact structures 234, and the interlayer contact structures 236 (e.g., using a CVD technique, an ALD technique, a PVD technique, an electroplating technique, and/or another type of deposition technique) in the cavities.

The deposition tool 102, the etch tool 108, the plating tool 112, and/or another semiconductor processing tool may continue to perform similar processing operations to forming the interconnect region 216 until a sufficient or desired arrangement of conductive layers and/or contact structures is achieved.

As shown in FIG. 7D, one or more of the semiconductor processing tools 102-114 form the dielectric layers 228b, the conductive layers 230b, and the bond interface contact structures 238. For example, the deposition tool 102 may deposit the dielectric layers 228b (e.g., using a CVD technique, an ALD technique, a PVD technique, and/or another type of deposition technique). Additionally, or alternatively, the deposition tool 102 may deposit the conductive layers 230b (e.g., using a CVD technique, an ALD technique, a PVD technique, and/or another type of deposition technique). Additionally, or alternatively, the etch tool 108 may remove portions of the second dielectric layers to form cavities in second dielectric layers, and the deposition tool 102 and/or the plating tool 112 may form the bond interface contact structures 238 in the cavities (e.g., using a CVD technique, an ALD technique, a PVD technique, an electroplating technique, and/or another type of deposition technique).

As indicated above, FIGS. 7A-7D are provided as an example. Other examples may differ from what is described with regard to FIGS. 7A-7D.

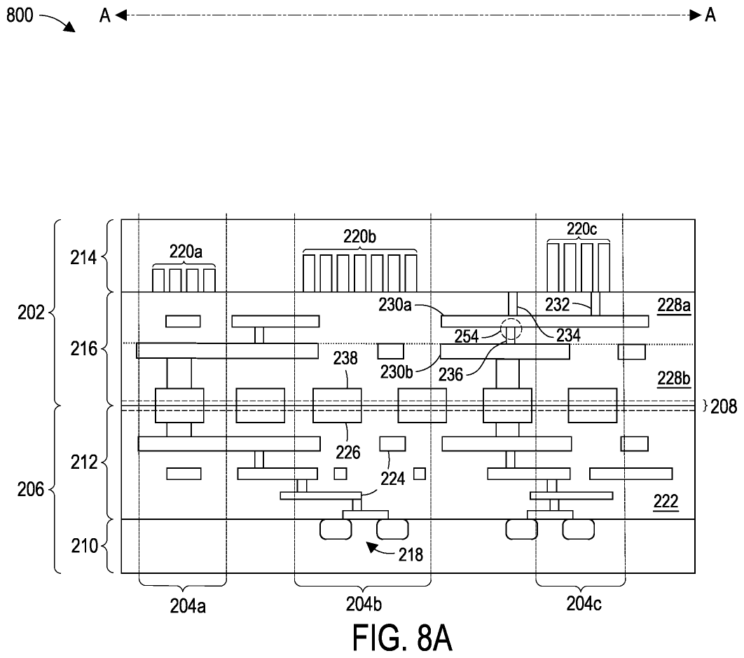

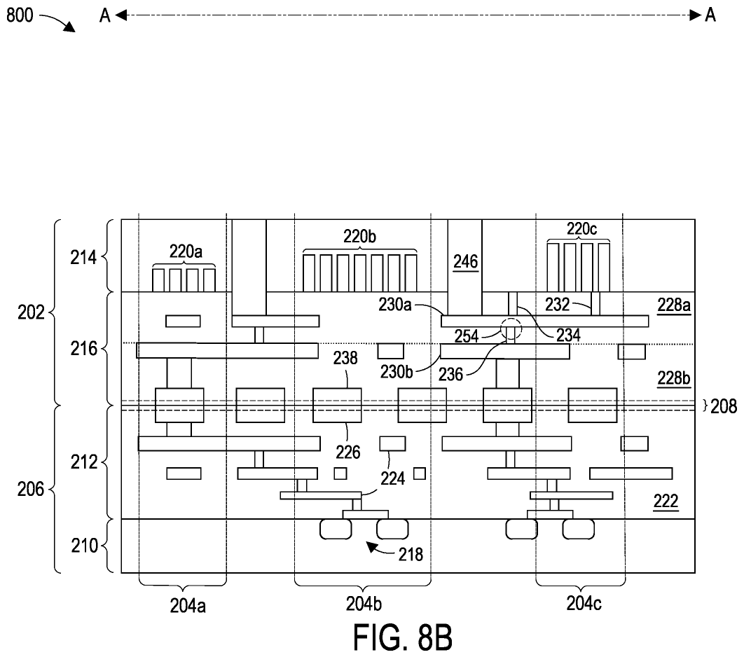

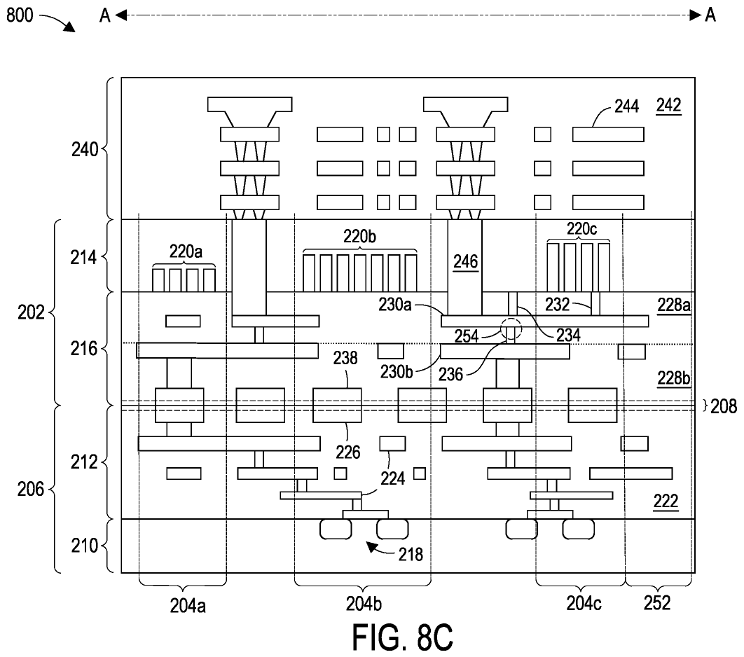

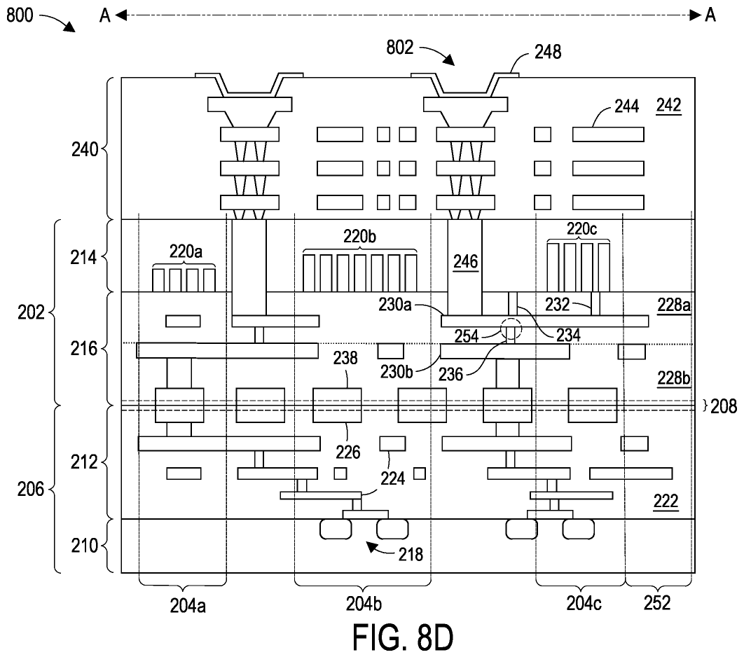

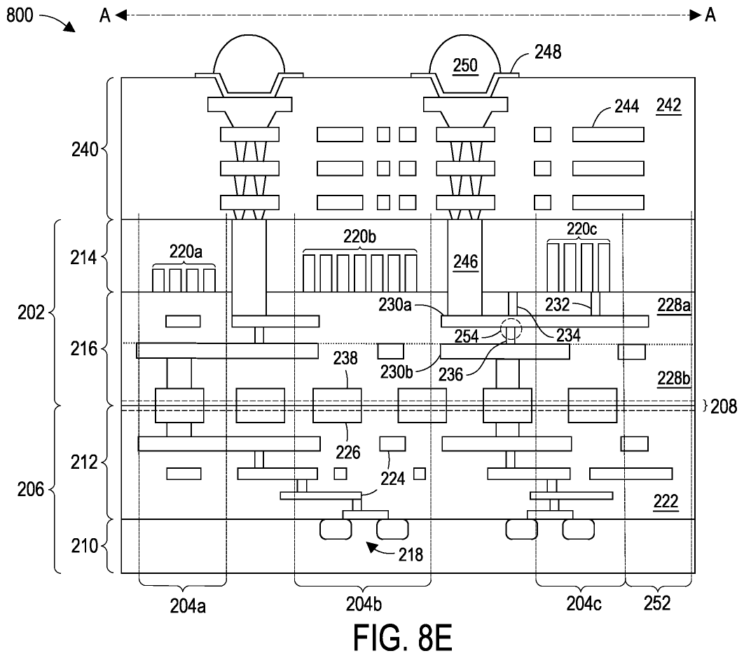

FIGS. 8A-8E are diagrams of an example implementation 800 of forming a portion of a semiconductor die package 200 described herein. In some implementations, one or more operations described in connection with FIGS. 8A-8E may be performed by one or more of the semiconductor processing tools 102-114 and/or the wafer/die transport tool 116. In some implementations, one or more operations described in connection with FIGS. 8A-8E may be performed by another semiconductor processing tool.

As shown in FIG. 8A, the first semiconductor die 202 and the second semiconductor die 206 may be bonded at the bonding interface 208 such that the first semiconductor die 202 and the second semiconductor die 206 are vertically arranged or stacked. The first semiconductor die 202 and the second semiconductor die 206 may be vertically arranged or stacked in a WoW configuration, a die on wafer configuration, a die on die configuration, and/or another direct bonding configuration. The bonding tool 114 may perform a bonding operation to bond the first semiconductor die 202 and the second semiconductor die 206 at the bonding interface 208. The bonding operation may include a direct bonding operation in which bonding of first semiconductor die 202 and the second semiconductor die 206 is achieved through the physical connection of the bond interface contact structures 226 with the bonding interface contact structures 238. At the bonding interface 208, a direct metal bonding is formed between the bond interface contact structures 226/238, and a direct dielectric bond is formed between two dielectric layers.

As shown in FIG. 8B, the one or more BTSV structures 246 may be formed through the device region 214 and into the interconnect region 216. To form the one or more BTSV structures 246, one or more of the semiconductor processing tools 102-114 may perform photolithography patterning operations, etching operations, deposition operations, CMP operations, and/or another type of operations to form the one or more BTSV structures 246. In this way, the one or more BTSV structures 246 extend through the semiconductor substrate the device region 214 and into the interconnect region 216. The one or more BTSV structures 246 may be electrically connected and/or physically connected with the one or more portions of the conductive layer 230a.

As shown in FIG. 8C, the redistribution region 240 of the semiconductor die package 200 may be formed over the first semiconductor die 202. One or more of the semiconductor processing tools 102-114 may form the redistribution region 240 by forming one or more dielectric layers 242 and forming a plurality of conductive layers 244 in the one or more dielectric layers 242. For example, the deposition tool 102 may deposit a first layer of the one or more dielectric layers 242 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first conductive layer of the plurality of conductive layers 244 in the recesses (e.g., using a CVD technique, an ALD technique, a PVD technique, an electroplating technique, and/or another type of deposition technique). At least a portion of the first conductive layer may be electrically connected and/or physically connected with the one or more BTSV structures 246. The deposition tool 102, the etch tool 108, the plating tool 112, and/or another semiconductor processing tool may continue to perform similar processing operations to forming the redistribution region 240 until a sufficient or desired arrangement of conductive layers 244 is achieved.

As shown in FIG. 8D, recesses 802 may be formed in the one or more dielectric layers 242. The recesses 802 may be formed to expose portions of a conductive layer 244 in the redistribution region 240. Thus, the recesses 802 may be formed over the one or more portions of a conductive layer 244.

In some implementations, a pattern in a photoresist layer is used to form the recesses 802. In these implementations, the deposition tool 102 forms the photoresist layer on the one or more dielectric layers 242. The exposure tool 104 exposes the photoresist layer to a radiation source to pattern the photoresist layer. The developer tool 106 develops and removes portions of the photoresist layer to expose the pattern. The etch tool 108 etches into the one or more dielectric layers 242 to form the recesses 802. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 802 based on a pattern.

As further shown in FIG. 8D, under bump metallization (UBM) layers 248 may be formed in the recesses 802. The deposition tool 102 and/or the plating tool 112 may deposit the UBM layers 248 using a CVD technique, a PVD technique, an ALD technique, an electroplating technique, another deposition technique described above in connection with FIG. 1, and/or a deposition technique other than as described above in connection with FIG. 1. In some implementations, a continuous layer of conductive material is deposited on the top surface of the redistribution region 240, including in the recess 802. The continuous layer of conductive material is then patterned (e.g., by the deposition tool 102, the exposure tool 104, and the developer tool 106) to form a pattern on the continuous layer of the conductive material, and the etch tool 108 removes portions of the continuous layer of the conductive material based on the pattern. Remaining portions of the continuous layer of the conductive material may correspond to the UBM layers 248.

As shown in FIG. 8E, conductive terminals 250 may be formed over the UBM layers 248. In some implementations, the plating tool 112 forms the conductive terminals 250 using an electroplating technique. In some implementations, solder is dispensed in the recesses 802 to form the conductive terminals 250.

As indicated above, FIGS. 8A-8E are provided as an example. Other examples may differ from what is described with regard to FIGS. 8A-8E.

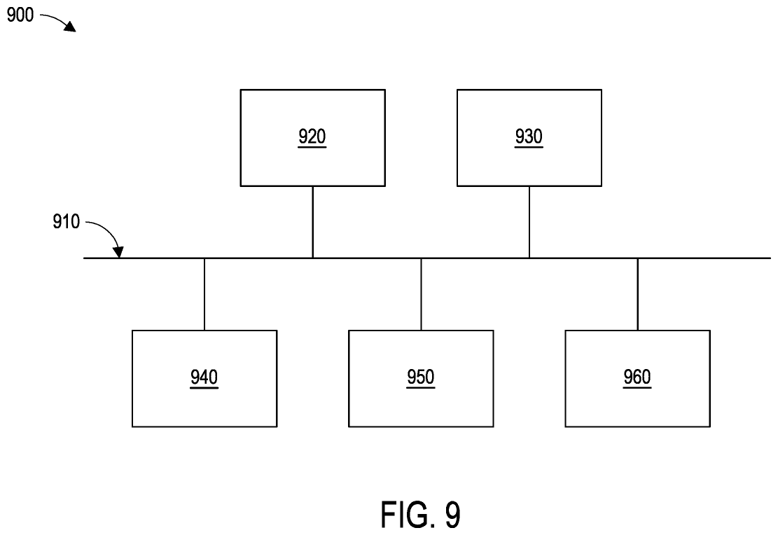

FIG. 9 is a diagram of example components of a device 900 associated with forming a structure to mitigate vertical interconnect access induced corrosion. The device 900 may correspond to one or more of the semiconductor processing tools 102-114 and/or the wafer/dic transport tool 116. In some implementations, one or more of the semiconductor processing tools 102-114 and/or the wafer/die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

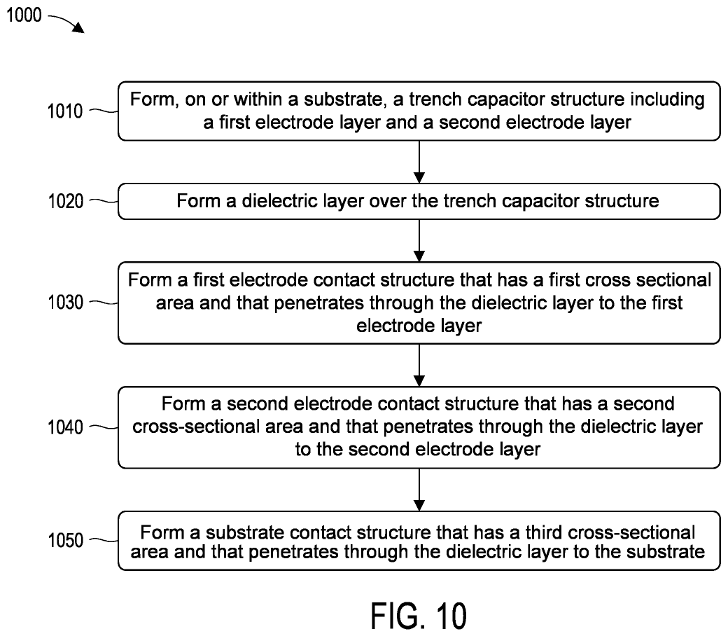

FIG. 10 is a flowchart of an example process 1000 associated with forming a structure to mitigate vertical interconnect access induced metal corrosion. In some implementations, one or more process blocks of FIG. 10 are performed by one or more semiconductor processing tools (e.g., one or more of the semiconductor processing tools 102-114 and/or the wafer/die transport tool 116). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming, on or within a substrate, a trench capacitor structure including a first electrode layer and a second electrode layer (block 1010). For example, one or more of the semiconductor processing tools 102-114 and/or the wafer/die transport tool 116 may form, on or within a substrate, a trench capacitor structure (e.g., the trench capacitor structure 220) including a first electrode layer (e.g., the conductive layer 402a) and a second electrode layer (e.g., the conductive layer 402b), as described herein.

As further shown in FIG. 10, process 1000 may include forming a dielectric layer over the trench capacitor structure (block 1020). For example, one or more of the semiconductor processing tools 102-114 and/or the wafer/die transport tool 116 may form a dielectric layer (e.g., at least one of the dielectric layers 228) over the trench capacitor structure, as described herein.

As further shown in FIG. 10, process 1000 may include forming a first electrode contact structure that has a first cross-sectional area and that penetrates through the dielectric layer to the first electrode layer (block 1030). For example, one or more of the semiconductor processing tools 102-114 and/or the wafer/die transport tool 116 may form a first electrode contact structure (e.g., the electrode contact structure 232a) that has a first cross-sectional area and that penetrates through the dielectric layer to the first electrode layer, as described herein.

As further shown in FIG. 10, process 1000 may include forming a second electrode contact structure that has a second cross-sectional area and that penetrates through the dielectric layer to the second electrode layer (block 1040). For example, one or more of the semiconductor processing tools 102-114 m and/or the wafer/die transport tool 116 may form a second electrode contact structure (e.g., the electrode contact structure 232b) that has a second cross-sectional area and that penetrates through the dielectric layer to the second electrode layer, as described herein.

As further shown in FIG. 10, process 1000 may include forming a substrate contact structure that has a third cross-sectional area and that penetrates through the dielectric layer to the substrate (block 1050). For example, one or more of the semiconductor processing tools 102-114 and/or the wafer/die transport tool 116 may form a substrate contact structure (e.g., the substrate contact structure 234) that has a third cross-sectional area and that penetrates through the dielectric layer to the substrate, as described herein.

Process 1000 may include additional implementations, such as any single implementation or any combination of implementations described below and/or in connection with one or more other processes described elsewhere herein.

In a first implementation, forming the first electrode contact structure, forming the second electrode contact structure, and forming the substrate contact structure includes performing a single photolithography masking operation to concurrently pattern the first electrode contact structure, the second electrode contact structure, and the substrate contact structure.

In a second implementation, alone or in combination with the first implementation, forming the first electrode contact structure, forming the second electrode contact structure, and forming the substrate contact structure includes performing a single dry etching operation to concurrently form cavities for the first electrode contact structure, the second electrode contact structure, and the substrate contact structure.

In a third implementation, alone or in combination with one or more of the first and second implementations, process 1000 includes forming a conductive layer (e.g., the conductive layer 230a) over the first electrode contact structure, the second electrode contact structure, and the substrate contact structure, where forming the conductive layer includes forming a portion that connects with the first electrode contact structure, and where forming the conductive layer includes forming a portion that connects with the second electrode contact structure and the substrate contact structure.

In a fourth implementation, alone or in combination with one or more of the first through third implementations, process 1000 includes forming a cavity (e.g., one or more of the cavities 408) for forming an interlayer contact structure (e.g., one or more of the interlayer contact structures 236) to the conductive layer.

In a fifth implementation, alone or in combination with one or more of the first through fourth implementations, forming the cavity includes performing a dry etching operation to form the cavity, and performing a wet clean operation (e.g., the wet clean operation 414) to clean the cavity.

In a sixth implementation, alone or in combination with one or more of the first through fifth implementations, performing the wet clean operation includes generating an electrical charge within the trench capacitor structure, and where a voltage drop (e.g., the voltage drop 510) between the trench capacitor structure and the substrate reduces a likelihood of the electrical charge discharging and causing damage to the conductive layer.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

Some implementations described herein provide techniques and apparatuses for forming a semiconductor die including a discharge management structure. The discharge management structure may include contact structures (e.g., vertical interconnect access structures, or “vias”) connecting a metal layer to electrode layers of a capacitor structure and to a substrate below the capacitor structure. The contact structures have different cross-sectional areas that, based on Kirchhoff's law, increase a voltage drop between the capacitor structure and the silicon substrate. The voltage drop may reduce a likelihood of an electrical discharge by the capacitor structure that causes damage to the metal layer. By reducing the likelihood of damage to the metal layer, defects that may be associated with vertical interconnect access induced metal island corrosion may be reduced.

In this way, a likelihood of defects attributable to VIMIC within the semiconductor die may decrease relative to another semiconductor die not including the discharge management structure. By decreasing the likelihood of such defects, a yield of the semiconductor die may increase to reduce an amount of resources needed to fabricate a volume of the semiconductor die (e.g., semiconductor manufacturing tools, raw materials, manpower, and/or computing resources).

As described in greater detail above, some implementations described herein provide a device. The device includes a trench capacitor structure. The trench capacitor structure includes a first set of electrode layers corresponding to a first voltage polarity and a second set of electrode layers corresponding to a second voltage polarity, where the second voltage polarity is different from the first voltage polarity. The device includes a first set of contact structures including a first subset of electrode contact structures that each has a first cross-sectional area and that connect the first set of electrode layers with a portion of a first conductive layer. The device includes a second set of contact structures including a second subset of electrode contact structures that each has a second cross-sectional area and that connect the second set of electrode layers with a portion of a second conductive layer, where the second cross-sectional area is greater relative to the first cross-sectional area.

As described in greater detail above, some implementations described herein provide a device. The device includes a capacitor structure. The device includes a first interlayer contact structure associated with a ground voltage for the capacitor structure. The device includes a second interlayer contact structure associated with a source voltage for the capacitor structure. The device includes a first electrode contact structure having a first cross-sectional area and connecting the first interlayer contact structure with a ground voltage electrode layer of the capacitor structure. The device includes a second conductive layer electrode contact structure having a second cross-sectional area and connecting the second interlayer contact structure with a source voltage electrode layer of the capacitor structure, where the second cross-sectional area is greater relative to the first cross-sectional area.

As described in greater detail above, some implementations described herein provide a method. The method includes forming, on or within a substrate, a trench capacitor structure including a first electrode layer and a second electrode layer. The method includes forming a dielectric layer over the trench capacitor structure. The method includes forming a first electrode contact structure that has a first cross-sectional area and that penetrates through the dielectric layer to the first electrode layer. The method includes forming a second electrode contact structure that has a second cross-sectional area and that penetrates through the dielectric layer to the second electrode layer. The method includes forming a substrate contact structure that has a third cross-sectional area and that penetrates through the dielectric layer to the substrate.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a trench capacitor structure comprising:
a first set of electrode layers corresponding to a first voltage polarity; and
a second set of electrode layers corresponding to a second voltage polarity,
wherein the second voltage polarity is different from the first voltage polarity;
a first set of contact structures comprising a first subset of electrode contact structures that each has a first cross-sectional area and that connect the first set of electrode layers with a portion of a first conductive layer; and
a second set of contact structures comprising a second subset of electrode contact structures that each has a second cross-sectional area and that connect the second set of electrode layers with a portion of a second conductive layer,
wherein the second cross-sectional area is greater relative to the first cross-sectional area.

2. The device of claim 1, wherein the first conductive layer and the second conductive layer are a same conductive layer.

3. The device of claim 2, wherein the same conductive layer comprises a layer of a metal material and further comprising:
a layer of a silicon nitride material on the layer of the metal material.

4. The device of claim 1, further comprising:
a seal ring structure, and
a seal ring contact structure connecting the first set of contact structures to the seal ring structure.

5. The device of claim 1, wherein the first subset of electrode contact structures or the second subset of electrode contact structures comprises:
at least one electrode contact structure comprising:
an approximately square cross-section, or
an approximately round cross-section.

6. The device of claim 1, wherein the second set of contact structures further comprises:
at least one substrate contact structure having a third cross-sectional area and that connects the portion of the first conductive layer to a substrate that is below the first set of electrode layers and the second set of electrode layers,
wherein the third cross-sectional area is greater relative to the first cross-sectional area.

7. The device of claim 6, wherein the second set of contact structures further comprises:
at least one electrode contact structure comprising:
an approximately rectangular cross-section, or
an approximately elliptical cross-section.

8. A device, comprising:
a capacitor structure;
a first interlayer contact structure associated with a ground voltage for the capacitor structure;
a second interlayer contact structure associated with a source voltage for the capacitor structure;
a first electrode contact structure having a first cross-sectional area and connecting the first interlayer contact structure with a ground voltage electrode layer of the capacitor structure; and
a second electrode contact structure having a second cross-sectional area and connecting the second interlayer contact structure with a source voltage electrode layer of the capacitor structure,
wherein the second cross-sectional area is greater relative to the first cross-sectional area.

9. The device of claim 8, wherein a ratio of the second cross-sectional area to the first cross-sectional area comprises:
a ratio that is included in a range of approximately 19:10 to approximately 21:10.

10. The device of claim 8, further comprising:
a conductive layer comprising a portion that connects the first interlayer contact structure and the first electrode contact structure.

11. The device of claim 10, further comprising:
a substrate contact structure having a third cross-sectional area and connecting the portion of the conductive layer to a substrate that is below the ground voltage electrode layer and below the source voltage electrode layer,
wherein the third cross-sectional area is greater relative to the second cross-sectional area.

12. The device of claim 11, wherein a ratio of the third cross-sectional area to the second cross-sectional area comprises:
a ratio that is included in a range of approximately 18:1 to approximately 22:1.

13. The device of claim 11, further comprising:
an etch stop layer above the conductive layer, and
wherein the first electrode contact structure, the second electrode contact structure, and the substrate contact structure are included as part of an electrical circuit that reduces a likelihood of an electrical discharge from the capacitor structure to the etch stop layer.

14. A method, comprising:
forming, on or within a substrate, a trench capacitor structure including a first electrode layer and a second electrode layer;
forming a dielectric layer over the trench capacitor structure;
forming a first electrode contact structure that has a first cross-sectional area and that penetrates through the dielectric layer to the first electrode layer;
forming a second electrode contact structure that has a second cross-sectional area and that penetrates through the dielectric layer to the second electrode layer; and
forming a substrate contact structure that has a third cross-sectional area and that penetrates through the dielectric layer to the substrate.

15. The method of claim 14, wherein forming the first electrode contact structure, forming the second electrode contact structure, and forming the substrate contact structure comprises:
performing a single photolithography masking operation to concurrently pattern the first electrode contact structure, the second electrode contact structure, and the substrate contact structure.

16. The method of claim 14, wherein forming the first electrode contact structure, forming the second electrode contact structure, and forming the substrate contact structure comprises:
performing a single dry etching operation to concurrently form cavities for the first electrode contact structure, the second electrode contact structure, and the substrate contact structure.

17. The method of claim 16, further comprising:
forming a conductive layer over the first electrode contact structure, the second electrode contact structure, and the substrate contact structure,
wherein forming the conductive layer includes forming a portion that connects with the first electrode contact structure, and
wherein forming the conductive layer includes forming a portion that connects with the second electrode contact structure and the substrate contact structure.

18. The method of claim 17, further comprising:
forming a cavity for forming a interlayer contact structure to the conductive layer.

19. The method of claim 18, wherein forming the cavity comprises:
performing a dry etching operation to form the cavity, and
performing a wet clean operation to clean the cavity.

20. The method of claim 19, wherein performing the wet clean operation comprises:
generating an electrical charge within the trench capacitor structure, and
wherein a voltage drop between the trench capacitor structure and the substrate reduces a likelihood of the electrical charge discharging and causing damage to the conductive layer.
